(19) United States
(12) Patent Application Publication
(10) Pub. No.: US 2025/0062210 A1
(43) Pub. Date: Feb. 20, 2025

(54) SEMICONDUCTOR PACKAGE COMPRISING DUMMY STRUCTURE AT CORNER REGION THEREOF

(71) Applicant: Samsung Electronics Co., Ltd., Suwon-si (KR)

(72) Inventors: Seongyo Kim, Suwon-si (KR); Minsoo Kim, Suwon-si (KR); Sang-Sick Park, Suwon-si (KR)

(21) Appl. No.: 18/433,887

(22) Filed: Feb. 6, 2024

(30) Foreign Application Priority Data
Aug. 18, 2023 (KR) 10-2023-0108595
Aug. 31, 2023 (KR) 10-2023-0115767

(51) Int. Cl. H01L 23/498; H01L 23/00; H01L 23/31; H01L 23/48; H01L 25/065

(52) U.S. Cl. CPC H01L 23/49838; H01L 23/3128; H01L 23/481; H01L 23/49822; H01L 24/16; H01L 24/32; H01L 24/48; H01L 24/73; H01L 25/0655; H01L 25/0657; H01L 2224/16225; H01L 2224/32225; H01L 2224/48228; H01L 2224/73204; H01L 2224/73265; H01L 2225/06517; H01L 2924/181

(57) ABSTRACT

A semiconductor package includes a first semiconductor die; a second semiconductor die on the first semiconductor die; and an underfill layer between the first semiconductor die and the second semiconductor die, where the first semiconductor die includes: a first substrate including a main region and first corner regions that are adjacent to respective corners of the second semiconductor die, and where the main region overlaps a center of the second semiconductor die; redistribution patterns that are on the first substrate and include dummy wirings and signal wirings; a redistribution insulating layer on the redistribution patterns; and conductive pads that are on the redistribution insulating layer and include dummy pads and signal pads, where a pattern density of a first set of the conductive pads on the first corner regions is greater than a pattern density of a second set of the conductive pads on the main region.

### CROSS-REFERENCE TO RELATED APPLICATIONS

This U.S. non-provisional patent application claims priority under 35 U.S.C. § 119 to Korean Patent Application No. 10-2023-0108595, filed on Aug. 18, 2023, and Korean Patent Application No. 10-2023-0115767, filed on Aug. 31, 2023, in the Korean Intellectual Property Office, the entire contents of which are hereby incorporated by reference.

### TECHNICAL FIELD

The present disclosure relates to a semiconductor package, and more particularly, relates to a semiconductor package including a dummy structure at a corner region thereof.

### BACKGROUND

Integrated circuit chips are typically provided with a semiconductor package to be suitably applied to circuit boards of electronic products or otherwise combined within an electronic system. In a general semiconductor package, an integrated circuit chip (or a semiconductor chip) may be mounted on a printed circuit board (PCB) and may be electrically connected to the PCB through bonding wires or bumps. Various studies for improving reliability and durability of semiconductor packages have been conducted with the development of an electronic industry.

### SUMMARY

An object of the present disclosure is to provide a semiconductor package with improved reliability.

The problem to be solved by the present disclosure is not limited to the problems mentioned above, and other problems not mentioned will be clearly understood by those skilled in the art from the description below.

A semiconductor package according to some embodiments of the present disclosure includes a first semiconductor die; a second semiconductor die on the first semiconductor die; and an underfill layer between the first semiconductor die and the second semiconductor die, where the first semiconductor die includes: a first substrate including a main region and first corner regions, where the first corner regions overlap the second semiconductor die, where the first corner regions are adjacent to respective corners of the second semiconductor die, and where the main region overlaps a center of the second semiconductor die in a first direction; redistribution patterns that are on the first substrate and include dummy wirings and signal wirings; a redistribution insulating layer on the redistribution patterns; and conductive pads that are on the redistribution insulating layer and include dummy pads and signal pads, where a pattern density of a first set of the conductive pads on the first corner regions is greater than a pattern density of a second set of the conductive pads on the main region.

A semiconductor package according to some embodiments of the present disclosure includes a first semiconductor die; a second semiconductor die on the first semiconductor die; a mold layer that overlaps the second semiconductor die and the first semiconductor die; external connection terminals on the first semiconductor die; internal connection members between the first semiconductor die and the second semiconductor die; and an underfill layer in a space between the first semiconductor die and the second semiconductor die, where the first semiconductor die includes: a first substrate including a main region and first corner regions, where the first corner regions overlap the second semiconductor die in a first direction, where the first corner regions are adjacent to respective corners of the second semiconductor die, and where the main region overlaps a center of the second semiconductor die; through vias that extend into the main region of the first substrate; redistribution patterns that are on the first substrate and include dummy wirings and signal wirings; a redistribution insulating layer on the redistribution patterns; and conductive pads that are on the redistribution insulating layer and include dummy pads and signal pads, where a distance between a first set of the conductive pads on the first corner regions is less than a distance between a second set of the conductive pads on the main region, where the second semiconductor die includes: a second substrate; an interlayer insulating layer on a lower surface of the second substrate; internal wirings in the interlayer insulating layer; and conductive bumps on the interlayer insulating layer, and where the internal connection members electrically connect at least some of the conductive bumps to ones of the signal pads.

A semiconductor package according to some embodiments of the present disclosure includes a first semiconductor die; a second semiconductor die on the first semiconductor die; and an underfill layer between the first semiconductor die and the second semiconductor die, where the first semiconductor die includes: a substrate including a main region and first corner regions, where the first corner regions overlap the second semiconductor die in a first direction, where the first corner regions are adjacent to respective corners of the second semiconductor die, and where the main region overlaps a center of the second semiconductor die; signal wirings and dummy wirings on the substrate; a redistribution insulating layer that is on the signal wirings and the dummy wirings; and conductive pads on the redistribution insulating layer, where the conductive pads include signal pads and dummy pads, and where a first one of the dummy wirings electrically connects a first one of the dummy pads and a first one of the signal pads.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a plan view of a semiconductor package according to embodiments of the present disclosure.

FIG. 2 is an enlarged view of portion ‘P1’ of FIG. 1 according to embodiments of the present disclosure.

FIG. 3 is a cross-sectional view taken along line A-A′ of FIG. 1.

FIG. 4 is an enlarged view of portion ‘P2’ of FIG. 3 according to embodiments of the present disclosure.

FIGS. 5A, 5B, and 5C are views sequentially showing a process of manufacturing a semiconductor package having an enlarged view of FIG. 4.

FIGS. 6A, 6B, 6C, 6D, 6E, 6F, 6G, 6H, and 6I are enlarged views of portion ‘P2’ of FIG. 3 according to embodiments of the present disclosure.

FIGS. 7A, 7B, and 7C are plan views of semiconductor packages according to embodiments of the present disclosure.

FIG. 8 is an enlarged partial plan view of a semiconductor package according to embodiments of the present disclosure.

FIG. 9 is a plan view of a semiconductor package according to embodiments of the present disclosure.

FIGS. 10A, 10B, 10C, 10D, 10E, 10F, 10G, 10H, and 10I are partial plan enlarged views of a semiconductor package according to embodiments of the present disclosure.

FIGS. 11A, 11B, and 11C are plan views of semiconductor packages according to embodiments of the present disclosure.

FIG. 12 is a cross-sectional view of a semiconductor package according to embodiments of the present disclosure.

FIG. 13 is a cross-sectional view of a semiconductor package according to embodiments of the present disclosure.

FIG. 14 is a cross-sectional view of a semiconductor package according to embodiments of the present disclosure.

FIG. 15 is a cross-sectional view of a semiconductor package according to embodiments of the present disclosure.

### DETAILED DESCRIPTION

To clarify the present disclosure, parts that are not connected with the description will be omitted, and the same elements or equivalents are referred to by the same reference numerals throughout the specification. Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

In addition, unless explicitly described to the contrary, the word “comprises”, and variations such as “comprises” or “comprising”, will be understood to imply the inclusion of stated elements but not the exclusion of any other elements. As used herein, the phrase “at least one of A, B, and C” refers to a logical (A OR B OR C) using a non-exclusive logical OR, and should not be construed to mean “at least one of A, at least one of B and at least one of C.” As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, steps, operations, elements and/or components, but do not preclude the presence or addition of one or more other features, steps, operations, elements, components and/or groups thereof. The term “and/or” includes any and all combinations of one or more of the associated listed items. The term “connected” may be used herein to refer to a physical and/or electrical connection and may refer to a direct or indirect physical and/or electrical connection. Components or layers described with reference to “overlap” in a particular direction may be at least partially obstructed by one another when viewed along a line extending in the particular direction or in a plane perpendicular to the particular direction.

Hereinafter, to explain the present disclosure in detail, embodiments according to the present disclosure will be described with reference to the accompanying drawings. In this specification, terms indicating order such as first, second, etc. are used to distinguish components that perform the same/similar functions, and their numbers may change depending on the order in which they are mentioned.

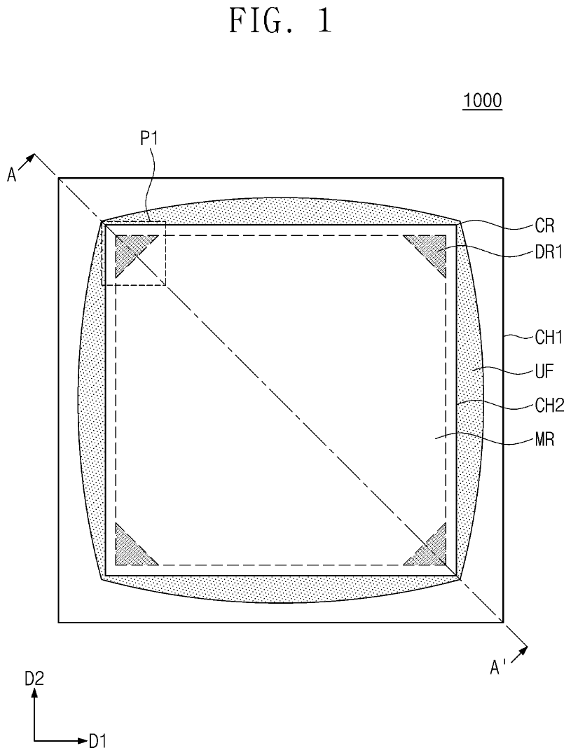

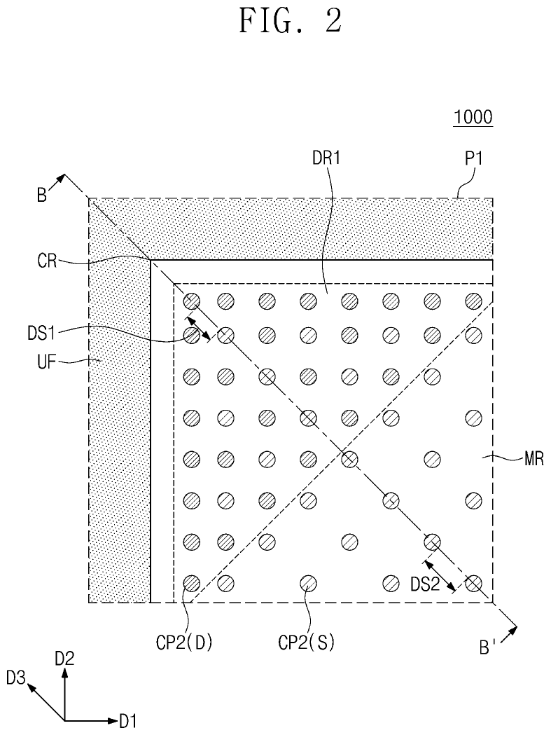

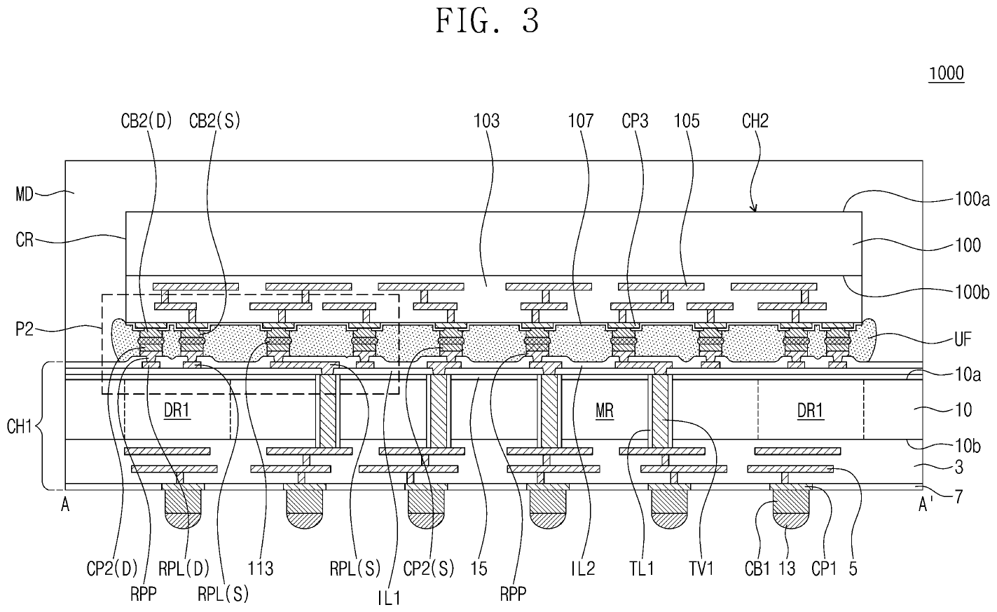

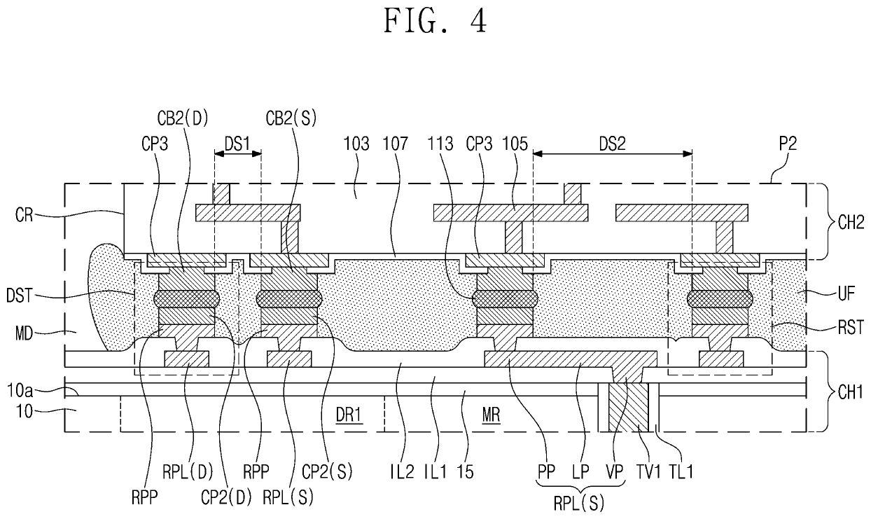

FIG. 1 is a plan view of a semiconductor package according to embodiments of the present disclosure. FIG. 2 is an enlarged view of portion ‘P1’ of FIG. 1 according to embodiments of the present disclosure. FIG. 3 is a cross-sectional view taken along line A-A′ of FIG. 1. FIG. 4 is an enlarged view of portion ‘P2’ of FIG. 3 according to embodiments of the present disclosure. FIG. 4 may be a part of a cross-section taken along line B-B′ of FIG. 2.

Referring to FIGS. 1 to 4, a semiconductor package 1000 according to the present embodiment includes a first semiconductor die CH1, an underfill layer UF, and a second semiconductor die CH2 sequentially stacked, and a mold layer MD covering or overlapping them. In this specification, ‘semiconductor die’ may also be referred to as ‘semiconductor chip’. The first semiconductor die CH1 and the second semiconductor die CH2 may be a memory die, a logic circuit die, or a buffer die.

The first semiconductor die CH1 includes a first substrate 10. The first substrate 10 may be a silicon single crystal substrate or a silicon on insulator (SOI) substrate. The first substrate 10 may include first corner regions DR1 and a main region MR. The first corner regions DR1 and the main region MR overlap the second semiconductor die CH2. The main region MR and the first corner regions DR1 are spaced apart from an edge of the first semiconductor die CH1. The first corner regions DR1 may be adjacent to corners CR of the second semiconductor die CH2, respectively. The main region MR may overlap the center of the second semiconductor die CH2. In the present example, the first corner regions DR1 may have a triangular shape when viewed in a plan view.

The first substrate 10 may include a first substrate front surface 10b and a first substrate back surface 10a that face each other. A first interlayer insulating layer 3 may be disposed on the first substrate front surface 10b. The first interlayer insulating layer 3 may have a single-layer or multi-layer structure of at least one of silicon oxide, silicon nitride, silicon oxynitride, and porous insulator.

First transistors (not shown) and multi-layered first internal wirings 5 may be disposed in the first interlayer insulating layer 3. First conductive pads CP1 may be disposed under the first interlayer insulating layer 3. First conductive bumps CB1 may be bonded to the first conductive pads CP1, respectively. The first internal wirings 5, the first conductive pads CP1, and the first conductive bumps CB1 may each include at least one metal selected from aluminum, tungsten, copper, titanium, and tantalum. A first solder layer 13 may be bonded under the first conductive bumps CB1. The first solder layer 13 may also be called an ‘external connection terminal’. The first solder layer 13 may be formed of SnAg, for example. A lower surface of the first interlayer insulating layer 3 may be covered or overlapped with a first passivation layer 7. The first passivation layer 7 may have a single-layer or multi-layer structure of at least one of SiN, SiCN, and polyimide.

The first substrate back surface 10a may be covered or overlapped with a first back insulating layer 15. The first back insulating layer 15 may be formed of, for example, silicon oxide. First through vias TV1 may extend into the first back insulating layer 15, the first substrate 10, and a portion of the first interlayer insulating layer 3. The first through via TV1 may include a metal such as copper or tungsten. A first via insulating layer TL1 may be interposed between the first through via TV1 and the first substrate 10. The first via insulating layer TL1 may be formed of silicon oxide. An air distance may be disposed within the first via insulating layer TL1.

A first redistribution insulating layer IL1 and a second redistribution insulating layer IL2 are sequentially stacked on the first back insulating layer 15. The first redistribution insulating layer IL1 and the second redistribution insulating layer IL2 may be formed of a photo-imagable dielectric (PID) resin. Redistribution patterns RPL are disposed between the first redistribution insulating layer IL1 and the second redistribution insulating layer IL2. The redistribution pads RPP are disposed on the second redistribution insulating layer IL2. The redistribution patterns RPL and the redistribution pads RPP may each include a metal such as copper. An upper surface of the second redistribution insulating layer IL2 may have a concave-convex structure due to the redistribution patterns RPL.

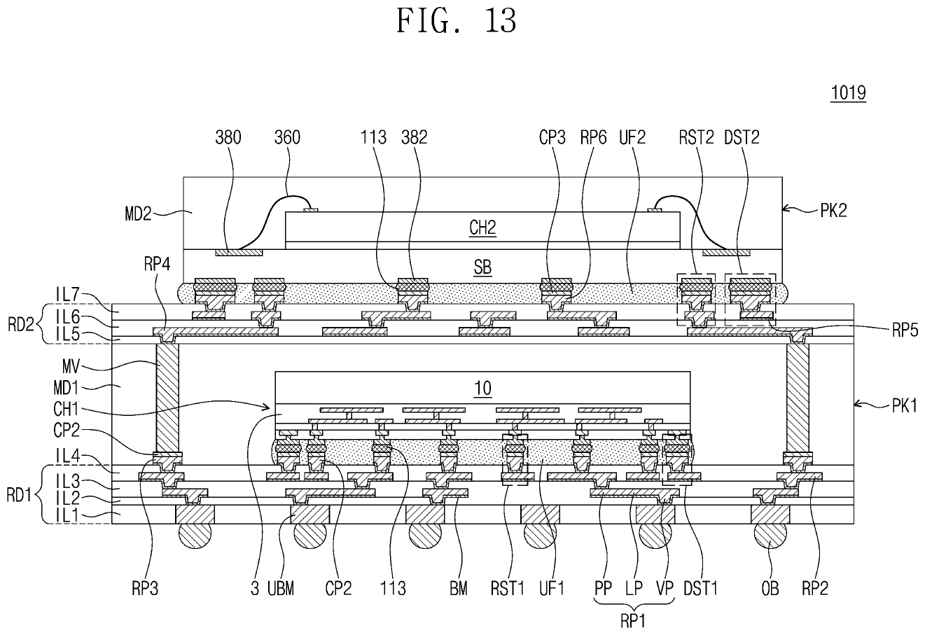

Although not shown in FIG. 3, lower surfaces of the redistribution patterns RPL and the redistribution pads RPP may be covered or overlapped with a diffusion barrier layer BM (in FIG. 13). The diffusion barrier layer may include at least one of titanium, titanium nitride, tantalum, tantalum nitride, and tungsten nitride. Each of the redistribution patterns RPL may have a via portion VP, a line portion LP, and a pad portion PP. The via portion VP may have a width that narrows as the via portion VP approaches the first substrate 10.

The via portion VP of the redistribution pattern RPL may extend into the first redistribution insulating layer IL1 and may be in contact with the first through via TV1. The line portion LP and the pad portion PP of the redistribution pattern RPL are disposed between the first redistribution insulating layer IL1 and the second redistribution insulating layer IL2. The redistribution patterns RPL may include signal wirings RPL(S) and dummy wirings RPL(D). Some of the signal wirings RPL(S) are disposed on the main region MR. Other portions of the signal wirings RPL(S) and the dummy wirings RPL(D) may be disposed on the first corner regions DR1. An electrical signal may be applied to the signal wirings RPL(S) and may be connected to the first through vias TV1 and/or the second semiconductor die CH2. The dummy wirings RPL(D) may be electrically floating. Alternatively, at least one of the dummy wirings RPL(D) may be connected to at least one of the signal wirings RPL(S).

A portion of the redistribution pad RPP may extend into the second redistribution insulating layer IL2 and may be in contact with the pad portion PP of the redistribution pattern RPL. A second conductive pad CP2 is disposed on the redistribution pad RPP. The second conductive pad CP2 may include at least one metal selected from gold and nickel. The second conductive pad CP2 may also be called a ‘wetting layer.’ The redistribution pad RPP and the second conductive pad CP2 are provided in plural. The second conductive pads CP2 may be two-dimensionally arranged in first and second directions D1 and D2 that intersect each other.

The second conductive pads CP2 may include signal pads CP2(S) and dummy pads CP2(D). Some of the signal pads CP2(S) are disposed on the main region MR. Other portions of the signal pads CP2(S) and dummy pads CP2(D) are disposed on the first corner regions DR1. The signal pads CP2(S) may be connected to the signal wirings RPL(S). The dummy pads CP2(S) may be connected to the dummy wirings RPL(D). The dummy pads CP2(D) may be electrically floating. Alternatively, at least one of the dummy pads CP2(D) may be electrically connected to at least one of the signal pads CP2(S).

The second semiconductor die CH2 includes a second substrate 100. The second substrate 100 may be a silicon single crystal substrate or a silicon on insulator (SOI) substrate. The second substrate 100 may include a second substrate front surface 100b and a second substrate back surface 100a facing each other. Second interlayer insulating layers 103 may be sequentially disposed under the second substrate front surface 100b. The second interlayer insulating layers 103 may each have a single-layer or multi-layer structure of at least one of silicon oxide, silicon nitride, silicon oxynitride, and a porous insulator.

First transistors (not shown) and multi-layered second internal wirings 105 may be disposed in the second interlayer insulating layer 103. Third conductive pads CP3 may be disposed under the second interlayer insulating layer 103. A lower surface of the second interlayer insulating layer 103 may be covered or overlapped with a second passivation layer 107. The second passivation layer 107 may cover or overlap a portion of side and upper surfaces of the third conductive pads CP3. Second conductive bumps CB2 may extend into the second passivation layer 107 and be bonded to the third conductive pads CP3, respectively. The second conductive bumps CB2 of the second semiconductor die CH2 may be respectively bonded to the second conductive pads CP2 of the first semiconductor die CH1 by second solder layers 113. The second solder layer 113 may also be called an ‘internal connection member’.

The second internal wirings 105, the third conductive pads CP3, and the second conductive bumps CB2 may each include at least one metal selected from aluminum, tungsten, copper, titanium, and tantalum. The second conductive bumps CB2 may include dummy bumps CB2(D) and signal bumps CB2(S). The signal bumps CB2(S) may be connected to the second internal wirings 105, and an electrical signal may be applied to the signal bumps CB2(S).

The second solder layer 113 may be formed of SnAg, for example. The second passivation layer 107 may have a single-layer or multi-layer structure of at least one of SiN, SiCN, and polyimide.

In the present example, the dummy wiring RPL(D), redistribution pad RPP, dummy pad CP2(D), second solder layer 113, and dummy bump CB2(D) that are sequentially stacked may constitute a dummy structure DST. The signal wiring RPL(S), redistribution pad RPP, signal pad CP2(S), second solder layer 113, and signal bump CB2(S) that are sequentially stacked may constitute a signal connection structure RST.

The underfill layer UF may be interposed between the first semiconductor die CH1 and the second semiconductor die CH2 and may fill a space therebetween. A portion (fillet portion) of the underfill layer UF may extend adjacent to the second semiconductor die CH2. The underfill layer UF may be formed of non-conductive film (NCF). The underfill layer UF may include a thermosetting resin or a photocurable resin. The underfill layer UF may further include an organic filler or an inorganic filler. The organic filler may include, for example, a polymer material. The inorganic filler may include, for example, silicon oxide (SiO₂).

The mold layer MD may cover or overlap upper and side surfaces of the second semiconductor die CH2, the fillet portion of the underfill layer UF, and an upper surface of the first semiconductor die CH1. For example, the mold layer MD may include an insulating resin such as epoxy-based molding compound (EMC). The mold layer MD may further include a filler, and the filler may be dispersed in the insulating resin.

A pattern density of the second conductive pads CP2 on the first corner regions DR1 is greater than a pattern density of the second conductive pads CP2 on the main region MR. In this specification, ‘pattern density’ may mean the number of patterns per unit area.

In a third direction D3 that intersects the first and second directions D1 and D2, a first distance DS1 between the second conductive pads CP2 on the first corner regions DR1 is smaller than a second distance DS2 between the second conductive pads CP2 in the main region MR. With this configuration, a distance between the second semiconductor die CH2 and the first semiconductor die CH1 on the first corner regions DR1 may be relatively narrowed, and a space to be filled by the underfill layer UF may also be relatively small. Accordingly, an unfill problem of the underfill layer UF on the first corner regions is inhibited.

When a pattern density of the second conductive pads CP2 on the first corner regions DR1 is the same as a pattern density of the second conductive pads CP2 on the main region MR, there is an increased possibility that the unfill problem of the underfill layer UF may occur in the first corner regions DR1. To prevent the unfill problem of the underfill layer UF, a thickness of the underfill layer UF has been conventionally increased. However, increasing the thickness of the underfill layer UF means that the fillet portion of the underfill layer UF is exposed on a side of the mold layer MD or the second or the possibility of non-wet defects occurring in which the solder layer 113 is not in contact with the second conductive pad CP2 also increase. This reduces the reliability of the semiconductor package. However, in the present disclosure, this problem may be prevented by the above configuration.

In order to improve the reliability of the semiconductor package, in the present disclosure, at least one of the dummy wirings RPL(D), the dummy pads CP2(D), and the dummy bumps CB2(D) may be additionally disposed other than the signal wirings RPL(S), signal pads CP2(S), and signal bumps CB2(S) are formed on the first corner regions (DR1) on the first corner regions DR1. The dummy wirings RPL(D), the dummy pads CP2(D), and the dummy bumps CB2(D) may not be disposed on the main region MR.

In the present example, some of the dummy pads CP2(D) may be disposed between signal pads CP2(S) on the first corner regions DR1. Additionally, some of the dummy pads CP2(D) may be disposed outside the signal pads CP2(S). As a result, some of the dummy pads CP2(D) may be closer to the corner CR and the edge of the second semiconductor die CH2 than the signal pads CP2(S). For example, the dummy pad CP2(D) and the signal pad CP2(S) adjacent to each other on the first corner regions DR1 may be spaced apart from each other by a first distance DS1.

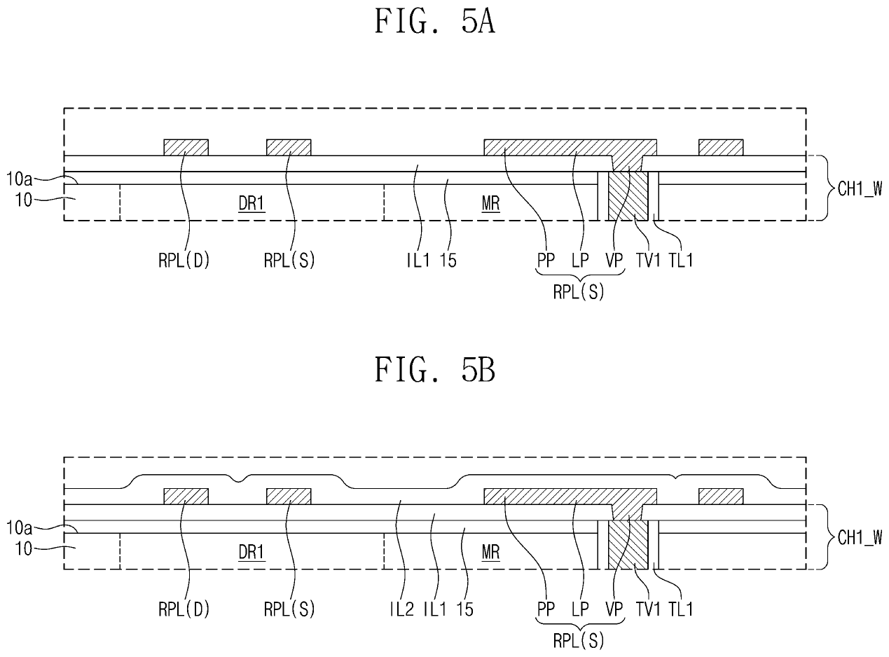

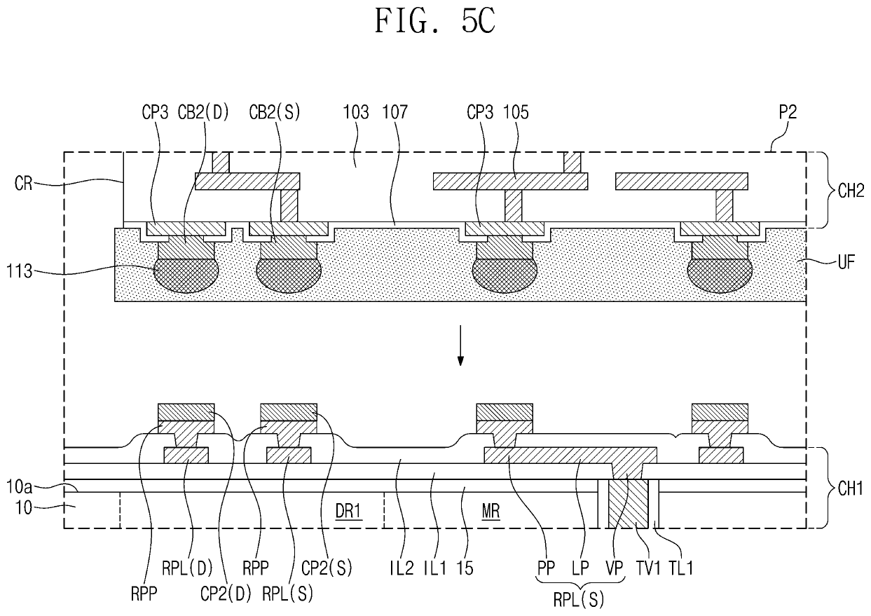

FIGS. 5A to 5C are views sequentially showing a process of manufacturing a semiconductor package having an enlarged view of FIG. 4.

Referring to FIGS. 3 and 5A, a first semiconductor die wafer CH1_W is prepared. The first semiconductor die wafer CH1_W may have device regions and separation regions therebetween. The first semiconductor die wafer CH1_W in each device region may have the internal structure described with reference to FIG. 3. A first through via TV1 and a first via insulating layer TL1 are formed on the first semiconductor die wafer CH1_W. A first interlayer insulating layer 3, first internal wirings 5, a first passivation layer 7, first conductive pads CP1, first conductive bumps CB1, and a first solder layer 13 are formed on the first substrate front surface 10b of the first semiconductor die wafer CH1_W. The first semiconductor die wafer CH1_W is bonded to the carrier substrate through an adhesive layer. The first substrate back surface 10a of the first semiconductor die wafer CH1_W is grounded to expose the first through via TV1 and the first via insulating layer TL1 to form a first back insulating layer 15.

A first redistribution insulating layer IL1 is formed on the first back insulating layer 15. The first redistribution insulating layer IL1 may be formed of a photo imagable dielectric (PID) resin. An exposure and development process is performed to form first via holes exposing the first through vias TV1 in the first redistribution insulating layer IL1. A first mask pattern (not shown) defining planar shapes of the redistribution patterns RPL is formed on the first redistribution insulating layer IL1, and a plating process is performed to form the redistribution patterns RPL. Then, the first mask pattern (not shown) is removed. Some of the redistribution patterns RPL fill the first via holes. Forming the redistribution patterns RPL may include forming signal wirings RPL(S) and dummy wirings RPL(D). That is, the signal wirings RPL(S) and the dummy wirings RPL(D) are formed simultaneously.

Referring to FIG. 5B, a second redistribution insulating layer IL2 is formed on the first redistribution insulating layer IL1 and the redistribution patterns RPL. The second redistribution insulating layer IL2 may be formed of a photo imagable dielectric (PID) resin. An upper surface of the second redistribution insulating layer IL2 may be formed to be curved (or have a concave-convex structure) by the redistribution patterns RPL.

Referring to FIG. 5C, exposure and development processes are performed to form second via holes exposing the redistribution patterns RPL in the second redistribution insulating layer IL2. A second mask pattern (not shown) defining planar shapes of the redistribution pads RPP is formed on the second redistribution insulating layer IL2, and plating processes are performed to form the redistribution pads RPP and conductive pads CP2. Then, the second mask pattern (not shown) is removed. Some of the redistribution pads (RPP) may be in the second via holes. Forming the second conductive pads CP2 may include forming signal pads CP2(S) and dummy pads CP2(D). That is, the signal pads CP2(S) and dummy pads CP2(D) are formed simultaneously.

Referring to FIGS. 3 and 5C, second semiconductor dies CH2 are prepared. Each of the second semiconductor dies CH2 may have the same structure as described with reference to FIG. 3. Each of the second semiconductor dies CH2 may include a second substrate 100, a second interlayer insulating layer 103, a second passivation layer 107, third conductive pads CP3, second conductive bumps CB2, and second solder layers 113. An underfill layer UF is formed below the second semiconductor dies CH2. The underfill layer UF may be formed by depositing a non-conductive layer (NCF) in a heated state. In this case, an edge of the underfill layer UF may have a right-angled cross section. The underfill layer UF may be formed to cover or overlap the second passivation layer 107, the second conductive bumps CB2, and the second solder layers 113. The second semiconductor dies CH2 on which the underfill layer UF is formed are arranged to correspond to each other on the device regions of the first semiconductor die wafer CH1_W.

Referring to FIGS. 3 and 5C, when a thermal compression process is performed, the second solder layers 113 of the second semiconductor dies CH2 extend into the underfill layer UF to be bonded to the second conductive pads CP2 of the first semiconductor die wafer CH1_W. In this case, a flux agent included in the NCF, which is the underfill layer UF, may remove an oxide layer on a surfaces of the second solder layers 113 and/or the second conductive pads CP2. In the thermal compression process, the NCF, which is the underfill layer UF, may also be compressed in a partially melted state and the second semiconductor dies CH2 may extend to have a fillet portion with a round cross-section next to the second semiconductor dies CH2.

In the method of manufacturing a semiconductor package according to the present disclosure, the dummy structure DST including at least one of the dummy wirings RPL(D), the dummy pads CP2(D), and the dummy bumps CB2(D) may be additionally disposed, in addition to the signal wirings RPL(S), the signal pads CP2(S), and signal bumps CB2(S) on the first corner regions DR1, and thus the space between the first semiconductor die wafer CH1_W and the second semiconductor die CH2 may become narrow. As a result, the size of the space to be filled by the underfill film UF is reduced, and the unfill problem of the underfill film UF does not occur in the first corner regions DR1. The thickness of the underfill layer UF may be thinned, and the underfill layer UF is not exposed to the side of the mold layer MD. As a result, the reliability of the semiconductor package 1000 may be improved.

Referring to FIGS. 3 and 5C, a mold layer MD is formed on the first semiconductor die wafer CH1_W using a mold. Subsequently, the adhesive layer and carrier substrate are removed from under the first semiconductor die wafer CH1_W. Then, a singulation process is performed to cut the separation region. Therefore, the semiconductor package 1000 of FIG. 3 may be manufactured.

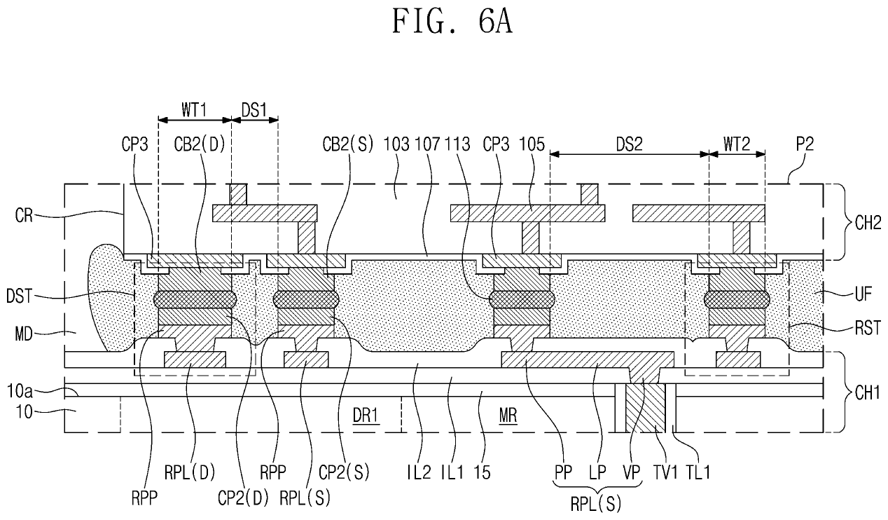

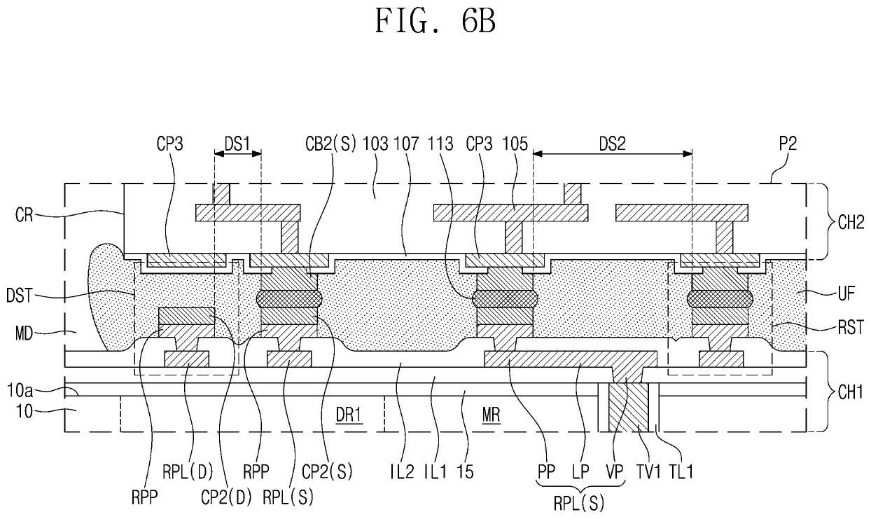

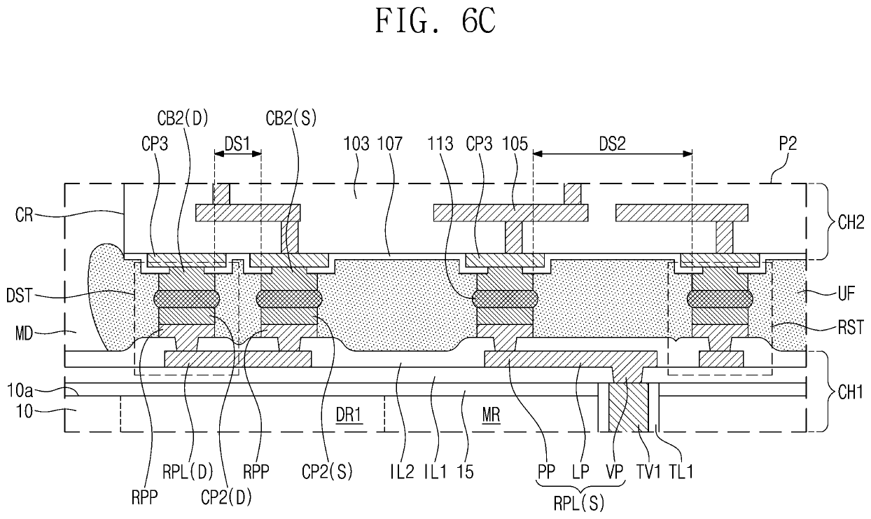

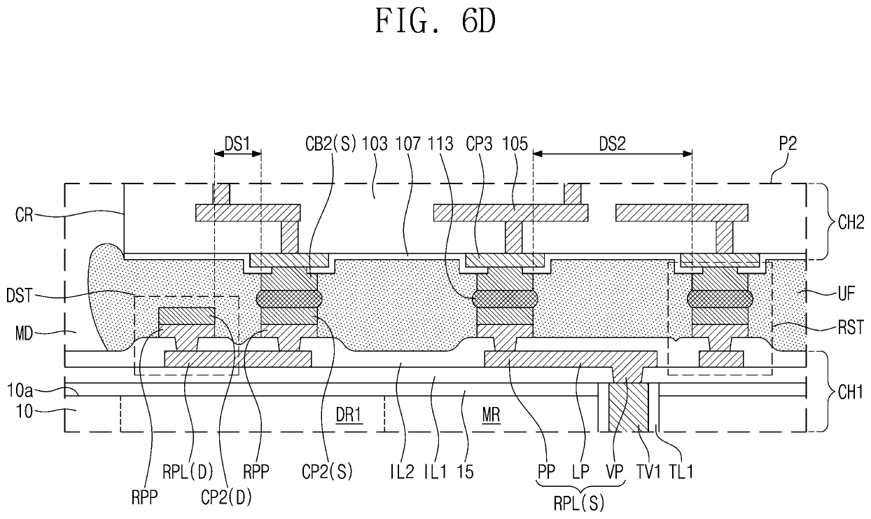

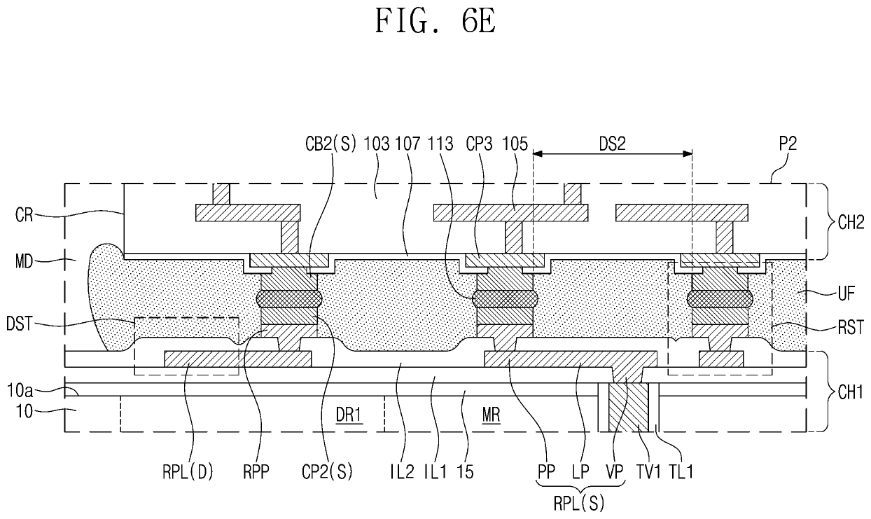

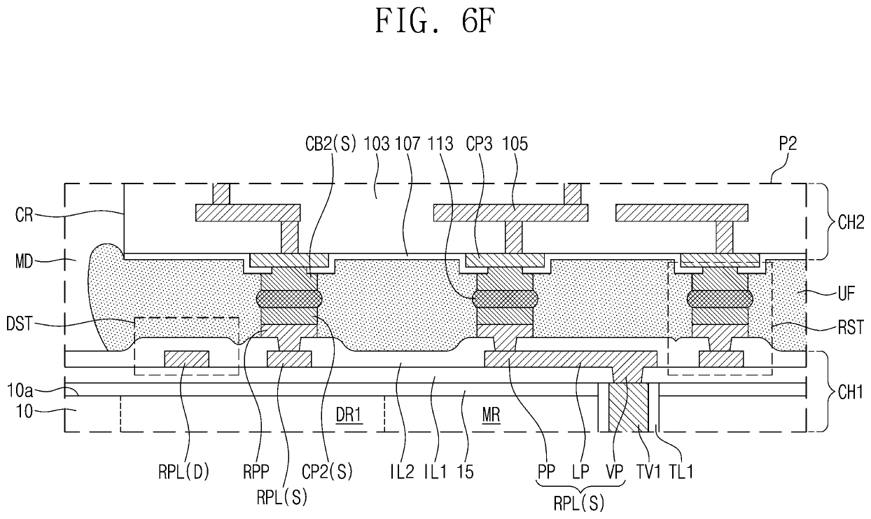

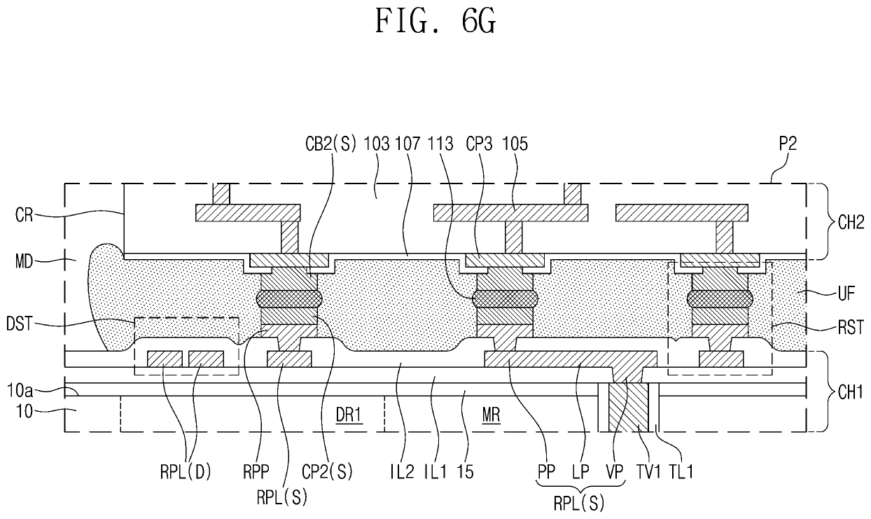

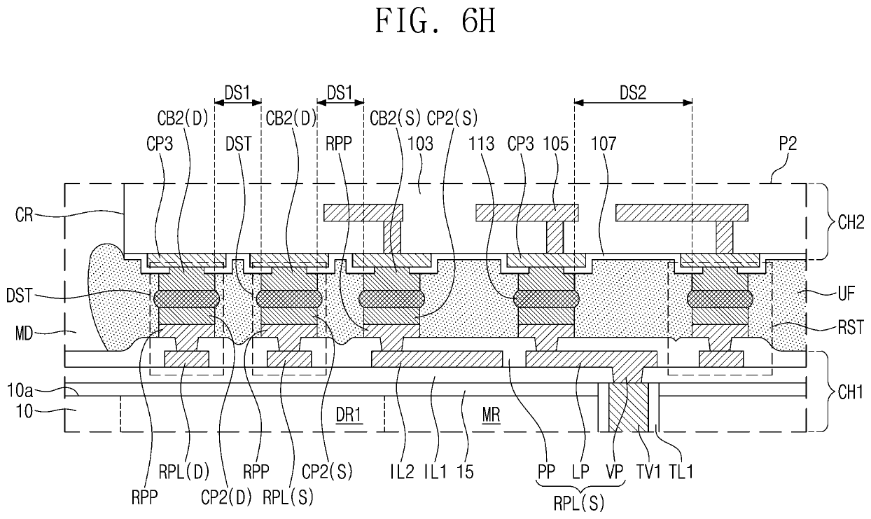

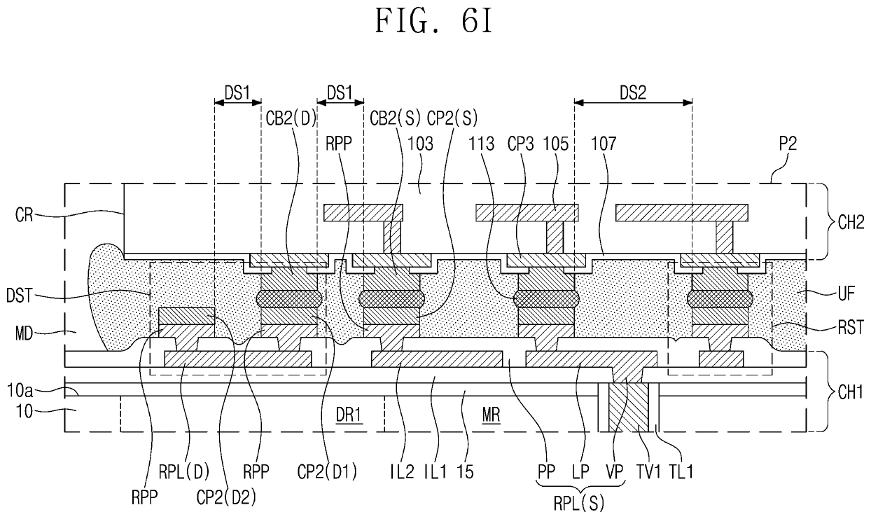

FIGS. 6A to 6I are enlarged views of portion ‘P2’ of FIG. 3 according to embodiments of the present disclosure.

Referring to FIG. 6A, in the present example, the dummy pad CP2(D) and/or the dummy bump CB2(D) may have a first width WT1. The signal pad CP2(S) and/or the signal bump CB2(S) may have a second width WT2 that is smaller than the first width WT1. Other structures may be the same/similar to those described with reference to FIG. 4.

Referring to FIG. 6B, in the present example, the second semiconductor die CH2 may not include the dummy bump CB2(D). The dummy pad CP2(D) is not in contact with the second solder layer 113, but is in contact with the underfill layer UF. The dummy structure DST according to the present example excludes the dummy bump CB2(D) and the second solder layer 113 below the dummy bump CB2(D). Other structures may be the same/similar to those described with reference to FIG. 4.

Referring to FIG. 6C, in the present example, the dummy wiring RPL(D) may connect the adjacent dummy pad CP2(D) and signal pad CP2(S). In this case, an electrical signal may be applied to the dummy wiring RPL(D), the dummy pad CP2(D), and the dummy bump CB2(D) through the signal pad CP2(S) connected thereto. Other structures may be the same/similar to those described with reference to FIG. 4.

Referring to FIG. 6D, in the present example, the dummy wiring RPL(D) may connect the dummy pad CP2(D) and the signal pad CP2(S) in the structure of FIG. 6B. The second semiconductor die CH2 may not include the dummy bump CB2(D). The dummy pad CP2(D) is not in contact with the second solder layer 113, but is in contact with the underfill layer UF. An electrical signal may be applied to the dummy wiring RPL(D) and the dummy pad CP2(D) through the signal pad CP2(S) connected thereto. The dummy structure DST according to the present example excludes the dummy bump CB2(D) and the second solder layer 113 below the dummy bump CB2(D). Other structures may be the same/similar to those described with reference to FIG. 4.

Referring to FIG. 6E, in the present example, the first semiconductor die CH1 may not include the dummy pads CP2(D). The second semiconductor die CH2 may not include the dummy bump CB2(D). The dummy wiring RPL(D) may be connected to the signal pad CP2(S) and may extend toward the corner CR of the second semiconductor die CH2. The dummy structure DST according to the present example may include only the dummy wiring RPL(D). Other structures may be the same/similar to those described with reference to FIG. 4.

Referring to FIG. 6F, in a present example, the first semiconductor die CH1 may not include the dummy pads CP2(D). The second semiconductor die CH2 may not include the dummy bump CB2(D). The dummy wiring RPL(D) is not connected to the signal pad CP2(S) and is spaced apart from the signal wiring RPL(S). The dummy structure DST according to the present example may include only the dummy wiring RPL(D). Other structures may be the same/similar to those described with reference to FIG. 4.

Referring to FIG. 6G, in the present example, the first semiconductor die CH1 may not include the dummy pads CP2(D). The second semiconductor die CH2 may not include the dummy bump CB2(D). The plurality of adjacent dummy wirings RPL(D) are not connected to the signal pad CP2(S) and are spaced apart from the signal wiring RPL(S). The dummy structure DST according to the present example may include only a plurality of adjacent dummy wirings RPL(D). Other structures may be the same/similar to those described with reference to FIG. 4.

Referring to FIG. 6H, a plurality of dummy structures DST are disposed on the first corner region DR1. Each of the dummy structures DST includes a dummy wiring RPL(D), a redistribution pad RPP, a dummy pad CP2(D), a second solder layer 113, and a dummy bump CB2(D). A first distance DS1 between adjacent dummy pads CP2(D) or between adjacent dummy bumps CB2(D) is larger than a second distance DS2 between adjacent signal pads CP2(S) or between adjacent signal bumps CB2(S). Other structures may be the same/similar to those described with reference to FIG. 4.

Referring to FIG. 6I, in a dummy structure DST according to the present example, one dummy wiring RPL(D) connects the first dummy pad CP2(D1) and the second dummy pad CP2(D2). The first dummy pad CP2(D1) is connected to the second solder layer 113 and the dummy bump CB2(D). An upper surface of the second dummy pad CP2(D2) may be in contact with the underfill layer UF without being in contact with the second solder layer 113. A first distance DS1 between adjacent dummy pads CP2(D) is greater than a second distance DS2 between adjacent signal pads CP2(S). Other structures may be the same/similar to those described with reference to FIG. 4.

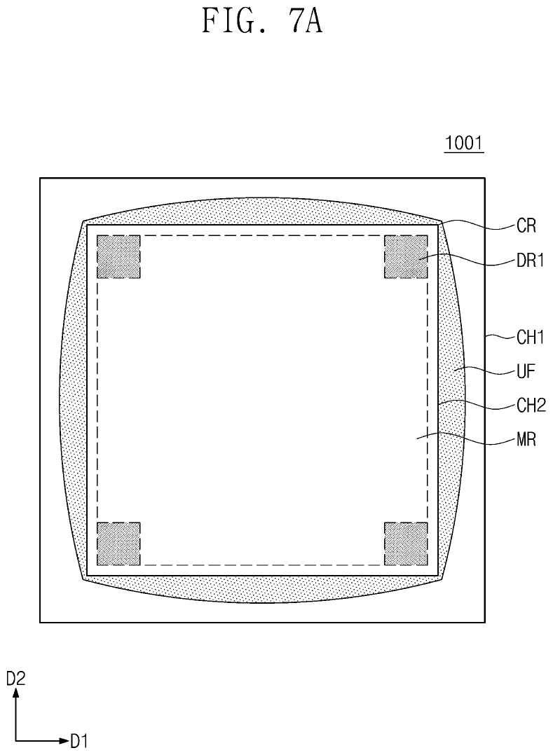

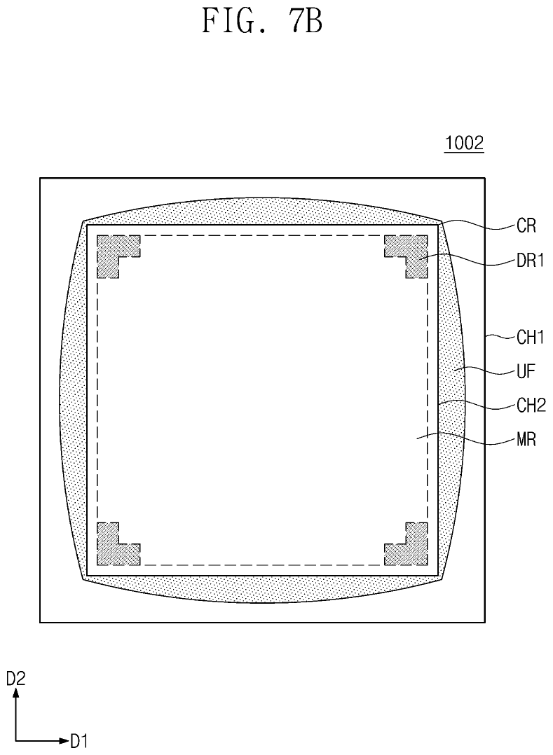

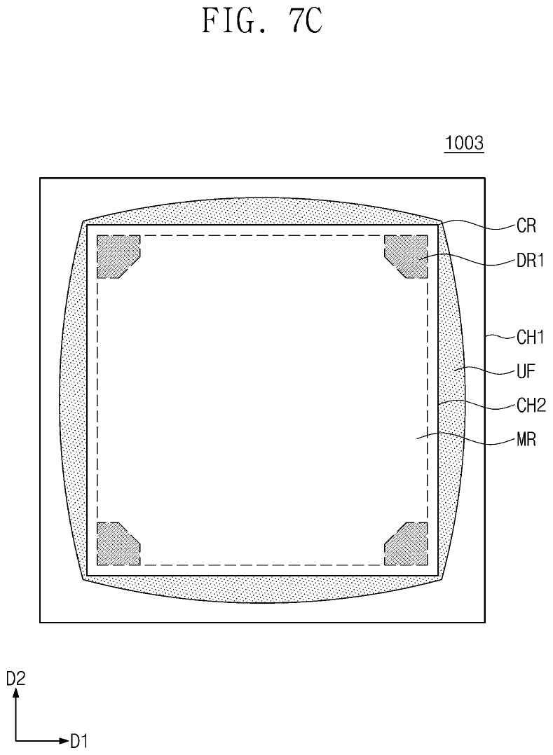

FIGS. 7A to 7C are plan views of semiconductor packages according to embodiments of the present disclosure.

Referring to FIG. 7A, in a semiconductor package 1001 according to the present example, first corner regions DR1 may have a square or rectangular shape when viewed in a plan view. Other structures may be the same/similar to those described above.

Referring to FIG. 7B, in a semiconductor package 1002 according to the present example, first corner regions DR1 may have a polygonal shape or an ‘L’ shape when viewed in a plan view. Other structures may be the same/similar to those described above.

Referring to FIG. 7C, in a semiconductor package 1003 according to the present example, first corner regions DR1 may have a pentagonal shape or a diamond shape when viewed in a plan view. Other structures may be the same/similar to those described above.

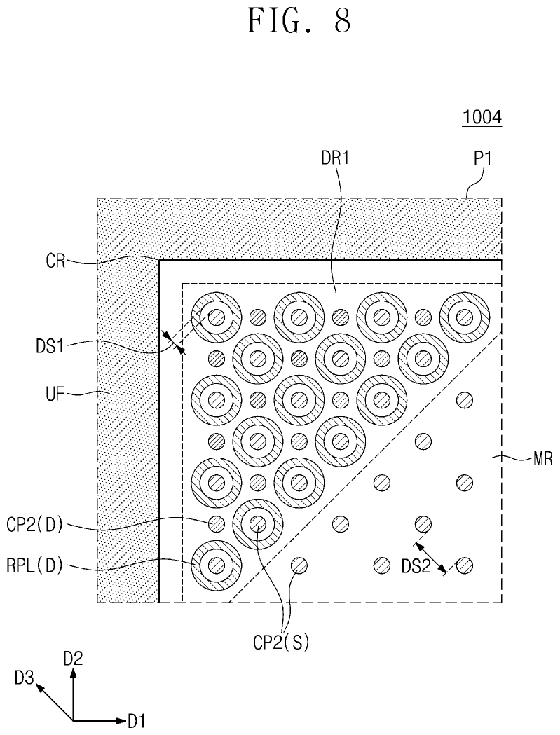

FIG. 8 is an enlarged partial plan view of a semiconductor package according to embodiments of the present disclosure.

Referring to FIG. 8, in a semiconductor package 1004 according to the present example, dummy wirings RPL(D) may have a ring shape surrounding the signal pad CP2(S). A first distance DS1 between the signal pad CP2(S) and the dummy wiring RPL(D) surrounding the signal pad CP2(S) may be smaller than a second distance DS2 between the signal pads CP2(S). The dummy wirings RPL(D) may be spaced apart from each other. The dummy pads CP2(D) may be disposed between the dummy wirings RPL(D). Other structures may be the same/similar to those described above.

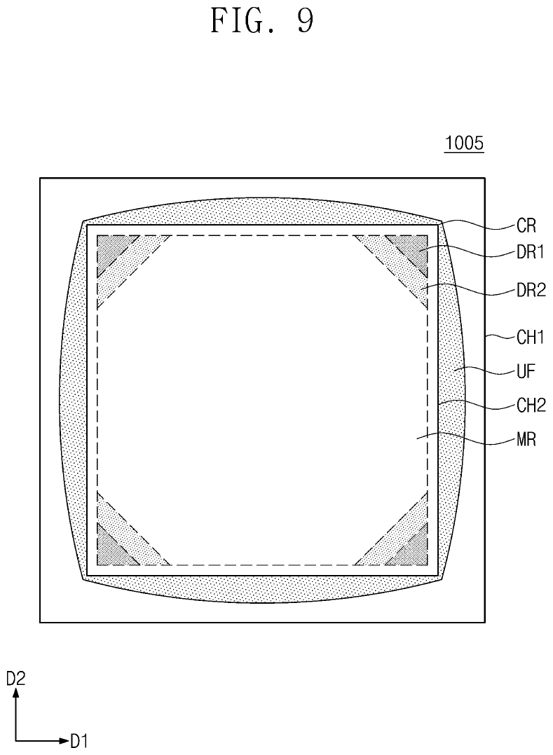

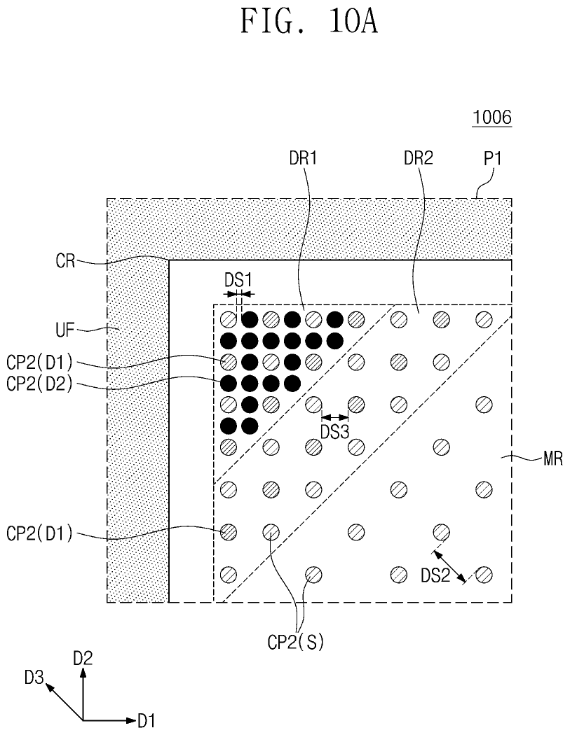

FIG. 9 is a plan view of a semiconductor package according to embodiments of the present disclosure.

Referring to FIG. 9, a first substrate 10 of a first semiconductor die CH1 of a semiconductor package 1005 according to the present example has a main region MR overlapping with a second semiconductor die CH2, first corner regions DR1, and second corner regions DR2. The main region MR, first corner regions DR1, and second corner regions DR2 are spaced apart from an edge of the first semiconductor die CH1. The main region MR may overlap a center of the second semiconductor die CH2. The first corner regions DR1 are closest to the corner CR of the second semiconductor die CH2. The second corner regions DR2 are disposed between the first corner regions DR1 and the main region MR. The first corner regions DR1 may have a triangle (or right-angled triangle or isosceles triangle) shape when viewed in a plan view. Each of the second corner regions DR2 may have a trapezoidal shape when viewed in a plan view. As described with reference to FIGS. 1 to 8, second conductive pads CP2 may be disposed in each of the first and second corner regions DR1 and DR2. The second conductive pads CP2 may include dummy pads CP2(D) and signal pads CP2(S).

A pattern density of the second conductive pads CP2 on the second corner regions DR2 is smaller than a pattern density of the second conductive pads CP2 on the first corner regions DR1, and is larger than the second conductive pads CP2 on the main region MR. A distance between the second conductive pads CP2 on the second corner regions DR2 is greater than a distance between the second conductive pads CP2 on the first corner regions DR1 and is smaller than a distance between the second conductive pads CP2 on the main region MR. A width of each of the second conductive pads CP2 on the second corner regions DR2 is smaller than a width of each of the second conductive pads CP2 on the first corner regions DR1, and is larger than a width of each of the second conductive pads CP2 on the main region MR. An area of each of the second conductive pads CP2 on the second corner regions DR2 is smaller than an area of each of the second conductive pads CP2 on the first corner regions DR1, and is larger than an area of each of the second conductive pads CP2 on the main region MR.

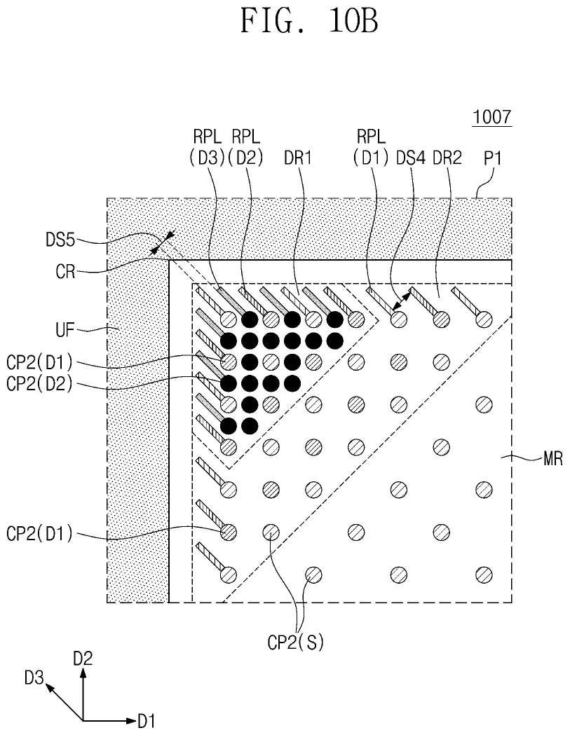

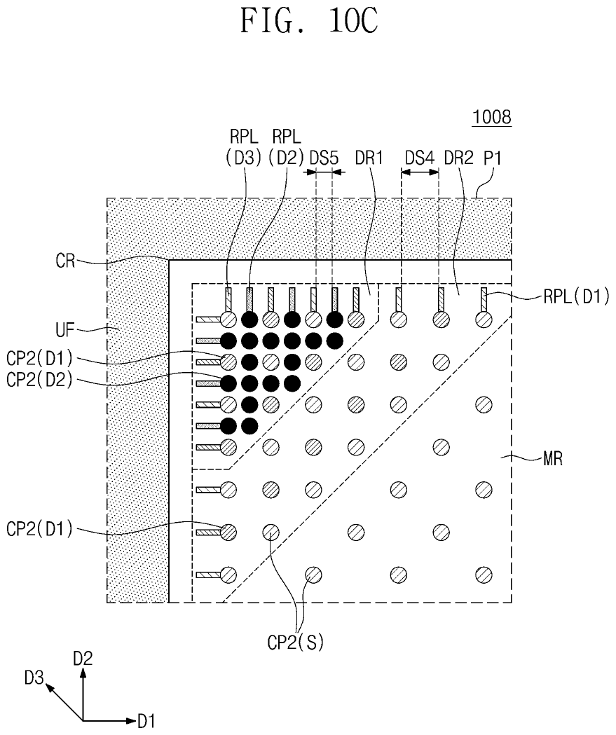

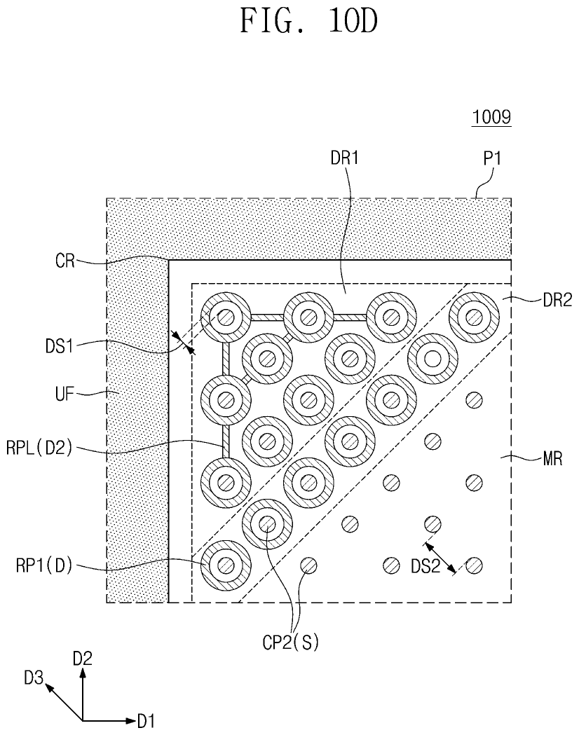

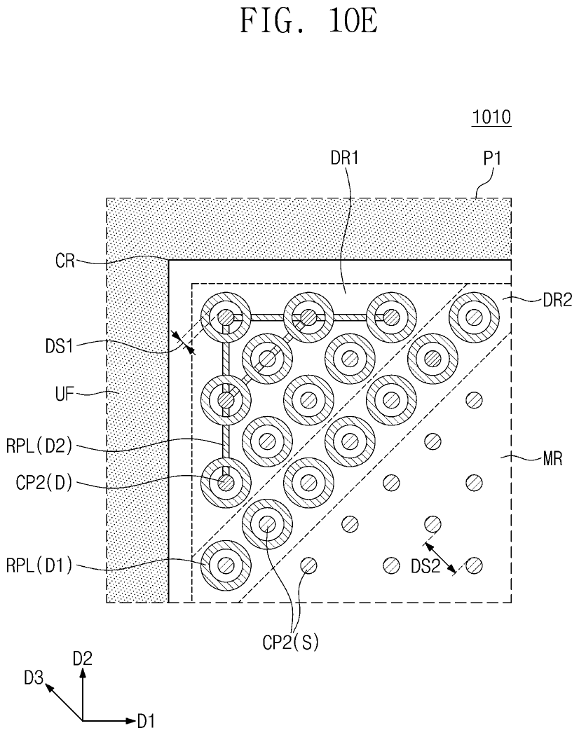

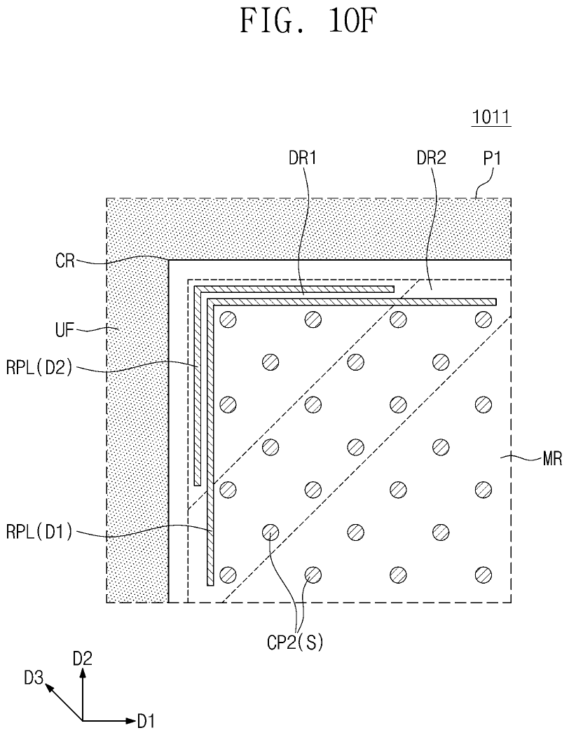

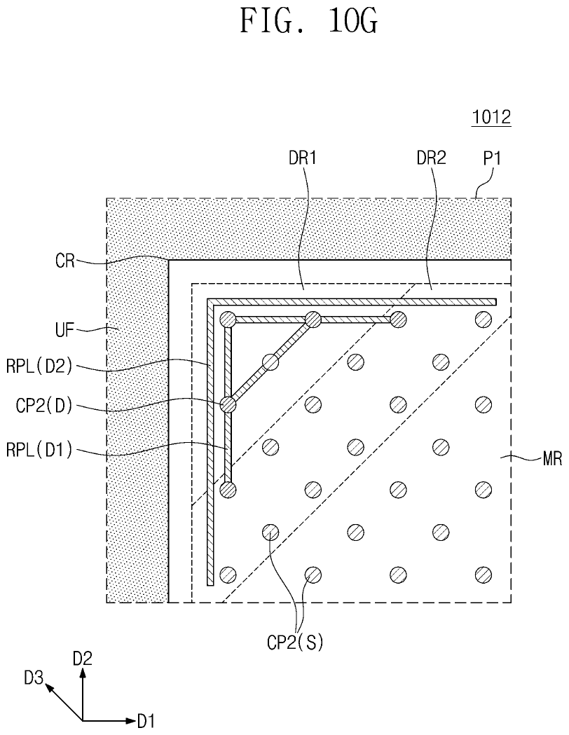

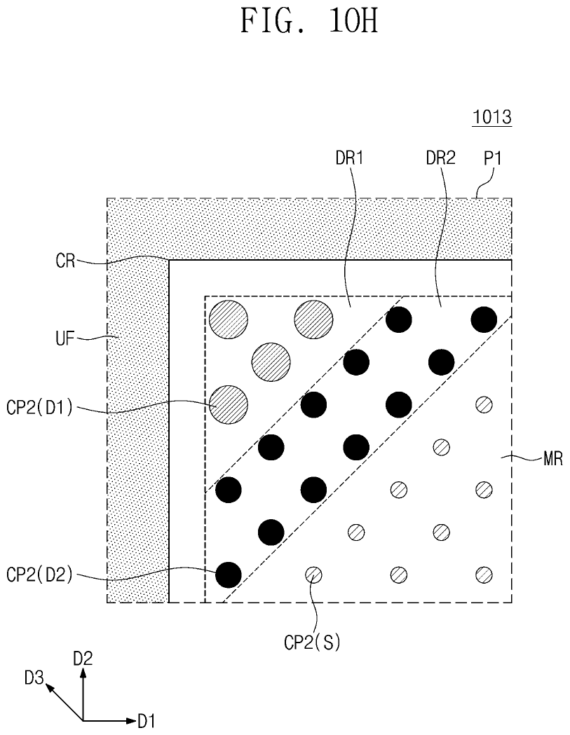

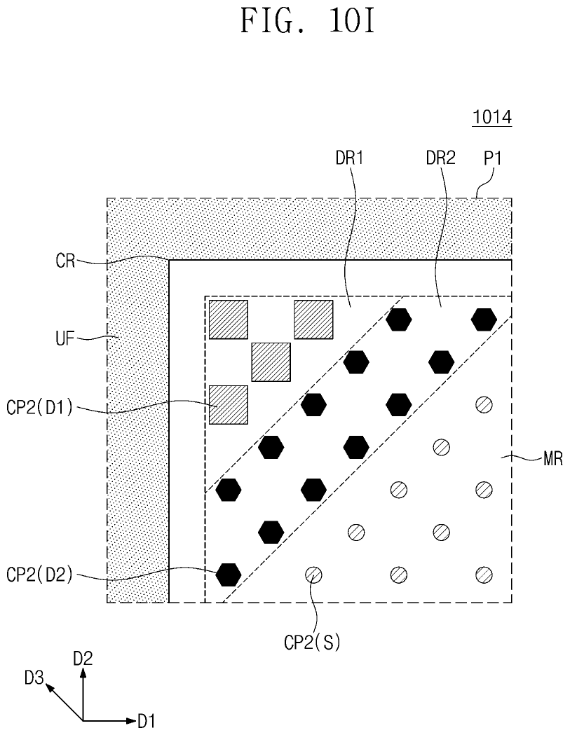

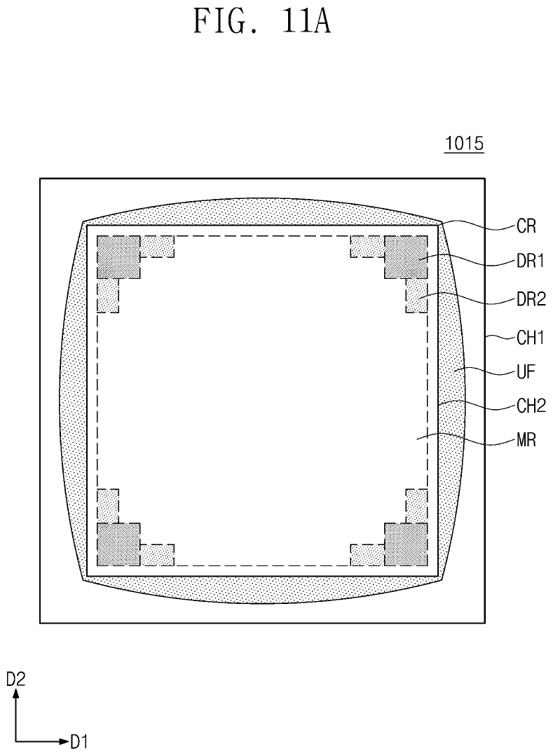

FIGS. 10A to 10I are partial plan enlarged views of a semiconductor package according to embodiments of the present disclosure.

Referring to FIG. 10A, in the semiconductor package 1006 according to the present example, second conductive pads CP2 may include signal pads CP2(S), a first dummy pad CP2(D1), and a second dummy pad CP2(D2). The signal pads CP2(S) with the second interval DS2 may be disposed on the main region MR. The first dummy pad CP2(D1) and second dummy pads CP2(D2) may be disposed between the signal pads CP2(S) on the first corner region DR1. On the first corner region DR1, the second conductive pads CP2 may be spaced apart from each other by a first distance DS1. The first dummy pad CP2(D1) may be disposed between the signal pads CP2(S) on the second corner region DR2. On the first corner region DR1, the second conductive pads CP2 may be spaced apart from each other by a third distance DS3. The third distance DS3 may be smaller than the second distance DS2 and may be larger than the first distance DS1.

Referring to FIG. 10B, in a semiconductor package 1007 according to the present example, second conductive pads CP2 may be arranged in the same manner as in FIG. 10A. A first dummy wiring RPL(D1) may be connected to the signal pad CP2(S) disposed on the outermost side. A second dummy wiring RPL(D2) may be connected to the first dummy pad CP2(D1) disposed on the outermost side. A third dummy wiring RPL(D3) may be connected to the second dummy pad CP2(D2) disposed on the outermost side. Each of the first to third dummy wirings (RPL(D1) to RPL(D3) may be elongated in the third direction D3. A fourth distance DS4 between the first and second dummy wirings RPL(D1) and RPL(D2) on the second corner region DR2 may be larger than a fifth distance DS5 between the first to third dummy wirings RPL(D1) to RPL(D3) on the first corner region DR1.

Referring to FIG. 10C, a semiconductor package 1008 according to the present example may have the same structure as the semiconductor package 1007 of FIG. 10B, except that longitudinal directions of the first to third dummy wirings RPL(D1) to RPL(D3) are in the first and second directions D1 and D2.

Referring to FIG. 10D, a semiconductor package 1009 according to the present example may exclude the dummy pads CP2(D). On the second corner region DR2, the first dummy wirings RPL(D) may have a ring shape surrounding the signal pad CP2(S). On the first corner region DR1, the first dummy wirings RPL(D1) may have a ring shape surrounding the signal pad CP2(S). On the first corner region DR1, the second dummy wirings RPL(D2) may connect some of the first dummy wirings RPL(D1). Other structures may be the same/similar to FIG. 8.

Referring to FIG. 10E, in a semiconductor package 1010 according to the present example, dummy pads CP2(D) may be disposed on the first corner region DR1. On the first corner region DR1, the first dummy wirings RPL(D1) may have a ring shape surrounding the second conductive pads CP2. On the first corner region DR1, the second dummy wirings RPL(D2) may connect some of the first dummy wirings RPL(D1), dummy pads CP2(D), and one signal pad CP2(S).

Referring to FIG. 10F, a semiconductor package 1011 according to the present example excludes the dummy pads CP2(D), but includes signal pads CP2(S) and a first dummy wiring RPL(D1) and a second dummy wiring RPL(D2). The first dummy wiring RPL(D1) and the second dummy wiring RPL(D2) may each have an ‘L’ shape. The first dummy wiring RPL(D1) may have a shorter length than the second dummy wiring RPL(D2). Both the first dummy wiring RPL(D1) and the second dummy wiring RPL(D2) are disposed on an edge of the first corner region DR1, and the first dummy wiring RPL(D1) is disposed on an edge of the second corner region DR2.

Referring to FIG. 10G, a semiconductor package 1012 according to the present example includes dummy pads CP2(D), signal pads CP2(S), a first dummy wiring RPL(D1), a second dummy wiring RPL(D2). The first dummy wiring RPL(D1) may have an ‘A’ shape. The second dummy wiring RPL(D2) may have an ‘L’ shape. The first dummy wiring RPL(D1) may have a shorter length than the second dummy wiring RPL(D2). The first dummy wiring RPL(D1) may connect a plurality of dummy pads CP2(D) and one signal pad CP2(S). An area occupied by the dummy wirings RPL(D1) and RPL(D2) on the first corner region DR1 may be greater than an area occupied by the dummy wirings RPL(D1) and RPL(D2) on the second corner region DR2.

Referring to FIG. 10H, in a semiconductor package 1013 according to the present example, the second conductive pads CP2 have the same shape as each other, but the areas thereof may increase as the second conductive pads CP2 approach the corner CR of the second semiconductor die CH2. For example, each of the first and second dummy pads CP2(D1) and CP2(D2) and the signal pads CP2(S) may be circular when viewed in a plan view. Only the first dummy pads CP2(D1) may be disposed on the first corner region DR1. Only the second dummy pads CP2(D2) may be disposed on the second corner region DR2. Only signal pads CP2(S) may be disposed on the main region MR. The area of each of the second dummy pads CP2(D2) may be smaller than the area of each of the first dummy pads CP2(D1), and may be larger than the area of each of the signal pads CP2(S). In another example, signal pads CP2(S) may be disposed on the first corner region DR1 and the second corner region DR2, and the shape and area thereof may be the same as those of the first dummy pads CP2(D1) and the second dummy pads CP2(D2) disposed on the first corner region DR1 and the second corner region DR2.

Referring to FIG. 10I, in a semiconductor package 1014 according to the present example, the second conductive pads CP2 may have different shapes, and areas thereof may increase as the second conductive pads CP2 approach the corner CR of the second semiconductor die CH2. For example, only first dummy pads CP2(D1) that are square when viewed in a plan view may be disposed on the first corner region DR1. Only second dummy pads CP2(D2) that have a regular hexagonal shape when viewed in a plan view may be disposed on the second corner region DR2. Only signal pads CP2(S) that are circular when viewed in a plan view may be disposed on the main region MR. The area of each of the second dummy pads CP2(D2) may be smaller than the area of each of the first dummy pads CP2(D1), and may be greater than the area of each of the signal pads CP2(S). In another example, signal pads CP2(S) may be disposed on the first corner region DR1 and the second corner region DR2, and shape and area thereof may be the same as those of the first dummy pads CP2(D1) and the second dummy pads CP2(D2) disposed on the first corner region DR1 and the second corner region DR2.

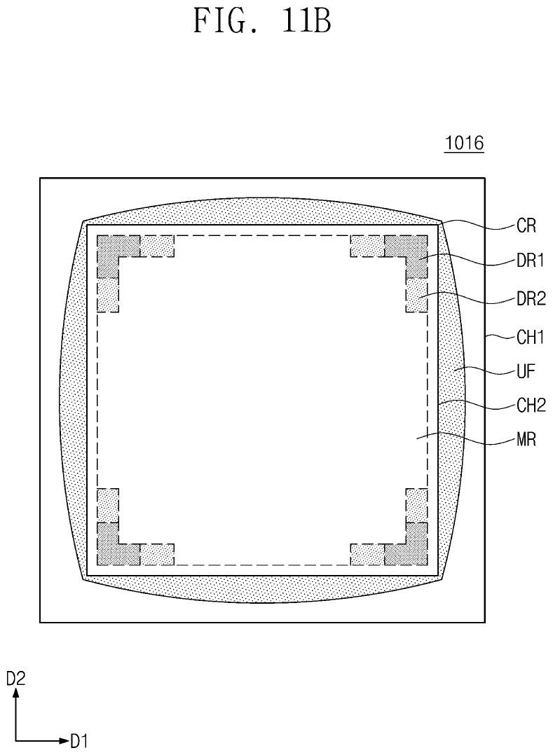

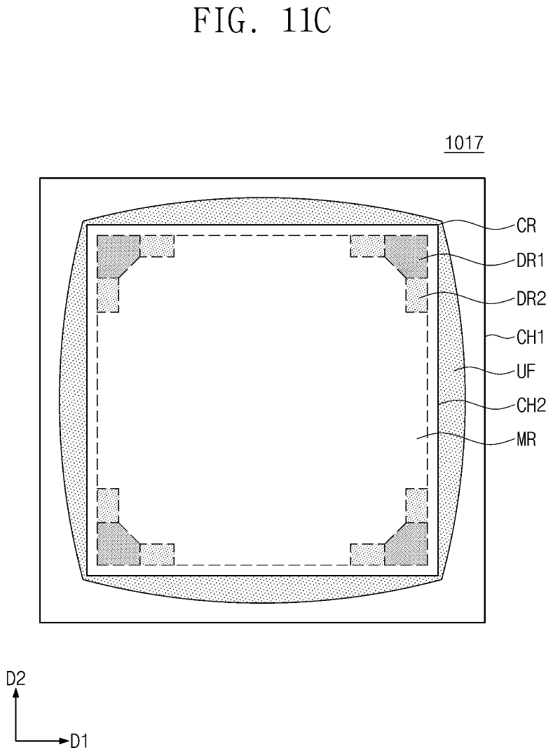

FIGS. 11A to 11C are plan views of semiconductor packages according to embodiments of the present disclosure.

Referring to FIG. 11A, in a semiconductor package 1015 according to the present example, the first corner regions DR1 may have a square or rectangular shape when viewed in a plan view. The second corner regions DR2 may have a square or rectangular shape when viewed in a plan view and may be adjacent to both sidewalls of the first corner regions DR1. The area of each of the second corner regions DR2 is smaller than the area of each of the first corner regions DR1. Other structures may be the same/similar to those described above.

Referring to FIG. 11B, in a semiconductor package 1016 according to the present example, the first corner regions DR1 may have a polygonal shape or an ‘L’ shape when viewed in a plan view. The second corner regions DR2 may have a square or rectangular shape when viewed in a plan view and may be adjacent to both sidewalls of the first corner regions DR1. The area of each of the second corner regions DR2 is smaller than the area of each of the first corner regions DR1. Other structures may be the same/similar to those described above. Referring to FIG. 11C, in a semiconductor package 1017 according to the present example, the first corner regions DR1 may have a pentagonal shape or a diamond shape when viewed in a plan view. The second corner regions DR2 may have a square or rectangular shape when viewed in a plan view and may be adjacent to both sidewalls of the first corner regions DR1. The area of each of the second corner regions DR2 is smaller than the area of each of the first corner regions DR1. Other structures may be the same/similar to those described above.

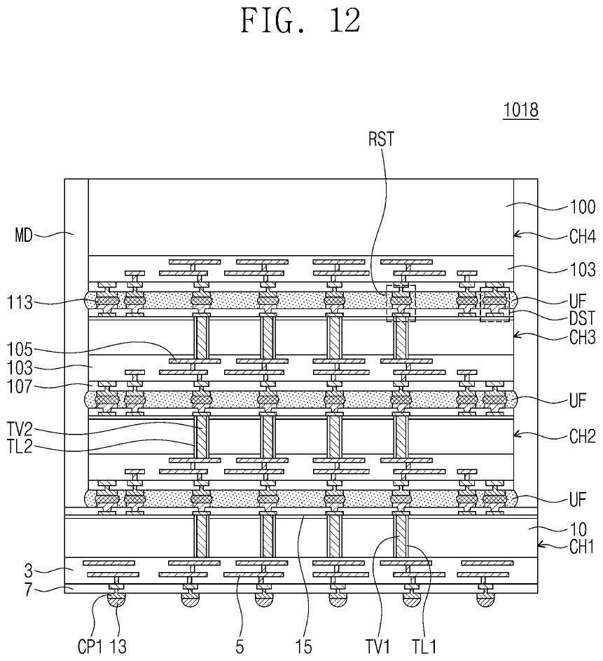

FIG. 12 is a cross-sectional view of a semiconductor package according to embodiments of the present disclosure.

Referring to FIG. 12, a semiconductor package 1018 according to the present example includes first to fourth semiconductor dies CH1 to CH4 sequentially stacked, an underfill layer UF interposed therebetween, and a mold layer MD covering them. The second to fourth semiconductor dies CH2 to CH4 may be memory dies that perform the same function. The first semiconductor die CH1 may have the same/similar structure as the first semiconductor die CH1 of FIG. 3. The first semiconductor die CH1 may be a buffer die. The semiconductor package 1018 may be a high bandwidth memory (HBM) chip. The semiconductor package 1018 may include dummy structures DST and signal connection structures RST disposed between the first to fourth semiconductor dies CH1 to CH4. The dummy structures DST and signal connection structures RST may be the same/similar to those described with reference to FIGS. 1 to 11C. Other structures may be the same/similar to those described above.

FIG. 13 is a cross-sectional view of a semiconductor package according to embodiments of the present disclosure.

Referring to FIG. 13, a semiconductor package 1019 according to the present example includes a first sub-semiconductor package PK1 and a second sub-semiconductor package PK2 stacked thereon. The first sub-semiconductor package PK1 includes a first redistribution substrate RD1, a first underfill layer UF1, a first semiconductor die CH1, a first mold layer MD1, and a mold via MV.

The first redistribution substrate RD1 may include first to fourth redistribution insulating layers IL1 to IL4 that are sequentially stacked. The first to fourth redistribution insulating layers IL1 to IL4 may each be formed as a PID. An under bump UBM may be interposed within the first redistribution insulating layer IL1. External connection terminals OB may be bonded to the under bumps UBM, respectively. The under bump UBM may be formed of a conductive material. The first redistribution substrate RD1 may include first to third redistribution patterns RP1, RP2, and RP3. Lower surfaces of the first to third redistribution patterns RP1, RP2, and RP3 may be covered or overlapped with a diffusion barrier layer BM. Second conductive pads CP2 may be disposed on the third redistribution pattern RP3. The diffusion barrier layer BM may include at least one of titanium, titanium nitride, tantalum, and tantalum nitride.

The mold vias MV are disposed on those disposed at the edges of the third redistribution pattern RP3. The mold vias MV may extend into the first mold layer MD1. Some third redistribution patterns RP3 may be bonded to the first semiconductor die CH1. First dummy structures DST1 and first signal connection structures RST1 may be disposed between the first semiconductor die CH1 and the first redistribution substrate RD1. The first dummy structures DST1 and the first signal connection structures RST1 may be the same/similar to those described with reference to FIGS. 1 to 11C.

A second redistribution substrate RD2 is disposed on the first mold layer MD1. The second redistribution substrate RD2 includes fifth to seventh redistribution insulating layers IL5 to IL7 that are sequentially stacked. The second redistribution substrate RD2 includes fourth to sixth redistribution patterns RP4, RP5, and RP6.

A second underfill layer UF2 is disposed on the second redistribution substrate RD2. The second sub-semiconductor package PK2 may be disposed on the second underfill layer UF2. The second sub-semiconductor package PK2 includes a package substrate SB, a second semiconductor die CH2 mounted thereon, and a second mold layer MD2 covering or overlapping the second semiconductor die CH2. The second semiconductor die CH2 may be electrically connected to the package substrate SB by, for example, a wire 360. The second semiconductor die CH2 is shown as a single semiconductor die or semiconductor chip, but may be a semiconductor package including a plurality of semiconductor dies of the same or different types.

Second dummy structures DST2 and second signal connection structures RST2 may be disposed between the second sub-semiconductor package PK2 and the second redistribution substrate RD2. The second dummy structures DST2 and the second signal connection structures RST2 may be the same/similar to those described with reference to FIGS. 1 to 11C.

The second semiconductor die CH2 may be an image sensor chip such as a CMOS imaging sensor (CIS), a memory device chip such as a flash memory chip, a DRAM chip, an SRAM chip, an EEPROM chip, a PRAM chip, an MRAM chip, a ReRAM chip, and a high bandwidth memory (HBM) chip, a hybrid memory cubic (HMC) chip, a microelectromechanical system (MEMS) device chip, or an application-specific integrated circuit (ASIC) chip.

The second mold layer MD2 may include the same material as the first mold layer MD1. The wire 360 may include copper or gold. The package substrate SB may be, for example, a double-sided or multi-layer printed circuit board. The package substrate SB includes an upper substrate pad 380 disposed on an upper surface thereof and a lower substrate pad 382 disposed on a lower surface thereof. Internal wiring (not shown) may be disposed within the package substrate SB to connect the upper substrate pad 380 and the lower substrate pad 382. The upper substrate pad 380 and the lower substrate pad 382 may include at least one of gold, copper, aluminum, and nickel. Other configurations may be the same/similar to those described above.

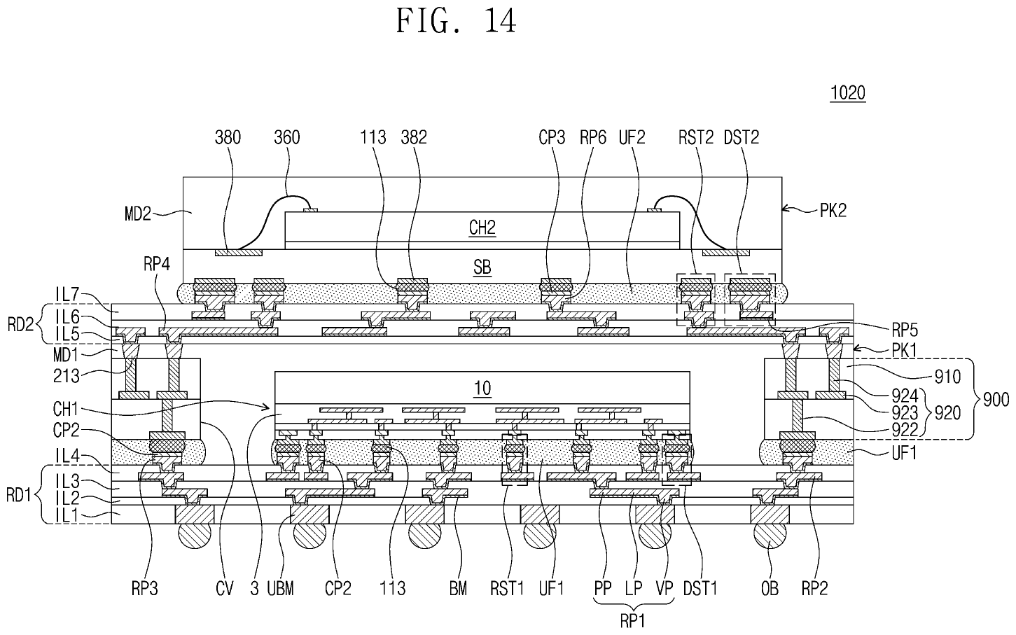

FIG. 14 is a cross-sectional view of a semiconductor package according to embodiments of the present disclosure.

Referring to FIG. 14, a first sub-semiconductor package PK1 included in the semiconductor package 1020 according to the present example includes a first redistribution substrate RD1, a connection substrate 900 mounted thereon, and a first semiconductor die CH1, a first mold layer MD1 covering or overlapping the first redistribution substrate RD1, the connection substrate 900, and the first semiconductor die CH1, and a second redistribution substrate RD2 thereon.

The connection substrate 900 may include/define a cavity region CV at a center thereof. The first semiconductor die CH1 may be disposed in the cavity region CV. The connection substrate 900 may include a plurality of base layers 910 and a conductive structure 920. The base layers 910 may include an insulating material. For example, the base layers 910 may include carbon-based materials, ceramics, or polymers. The conductive structure 920 may include a connection pad 921, a first connection via 922, a connection wiring 923, and a second connection via 924.

An underfill layer UF and a second underfill layer UF2 may be interposed between the connection substrate 900 and the first redistribution substrate RD1. A space between an inner wall of the cavity region CV of the connection substrate 900 and the first semiconductor die CH1 may be filled with the first mold layer MD1.

An auxiliary via 213 may penetrate the first mold layer MD1 and may connect the second connection via 924 of the connection substrate 900 and the third redistribution pattern RP3 of the second redistribution substrate RD2. Other configurations may be the same/similar to those described with reference to FIG. 13.

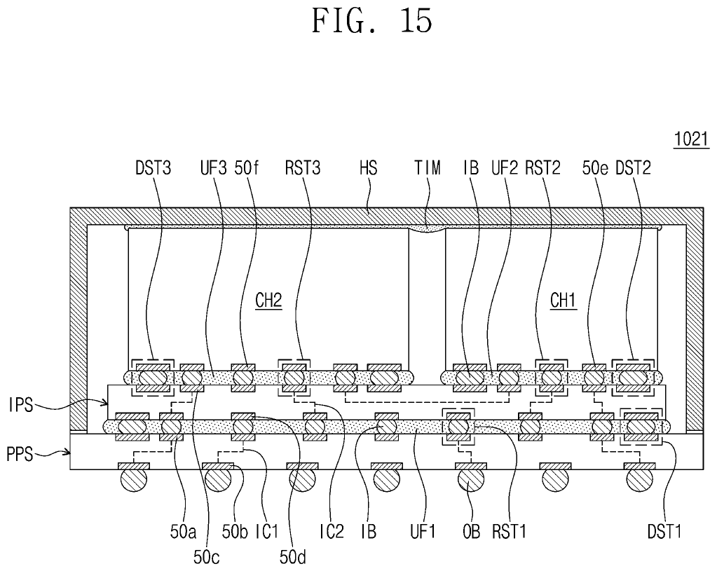

FIG. 15 is a cross-sectional view of a semiconductor package according to embodiments of the present disclosure.

Referring to FIG. 15, a semiconductor package 1006 according to the present example may include an interposer substrate IPS disposed on a package substrate PPS, first and second dies CH1 and CH2 mounted side by side on the interposer substrate IPS, and a heat dissipation member HS covering or overlapping the interposer substrate IPS and the first and second dies CH1 and CH2. The first and second semiconductor dies CH1 and CH2 may also be called ‘semiconductor devices’ or ‘semiconductor chips’. The first semiconductor die CH1 may be a central processing unit (CPU) chip or an application-specific integrated circuit (ASIC) chip. The second semiconductor die CH2 may be, for example, an HBM chip.

The package substrate PPS may be a printed circuit board. The package substrate PPS may include first upper conductive pads 50a, first lower conductive pads 50b, and first internal wirings IC1 connecting the first upper and lower conductive pads 50a, 50b. External connection terminals OB may be bonded to the first lower conductive pads 50b.

The interposer substrate IPS may include second upper conductive pads 50c, second lower conductive pads 50d, and second internal wirings IC2. The interposer substrate IPS may be a printed circuit board or a silicon interposer. When the interposer substrate IPS is a silicon interposer, the interposer substrate IPS may have a structure similar to the first semiconductor die 10 of FIG. 3. The interposer substrate IPS may include a silicon substrate, an interlayer insulating layer disposed thereon, and second internal wirings IC2 disposed in the interlayer insulating layer. The interposer substrate IPS may further include a through via that penetrates or extends into the silicon substrate.

The interposer substrate IPS may be bonded to the first upper conductive pads 50a of the package substrate PPS through internal connection terminals IB. A first underfill layer UF1 may be interposed between the interposer substrate IPS and the package substrate PPS. A first dummy structure DST1 and a first signal connection structure RST1 may be disposed between the package substrate PPS and the interposer substrate IPS. The first dummy structure DST1 and the first signal connection structure RST1 may be the same/similar to those described with reference to FIGS. 1 to 11C.

The first semiconductor die CH1 may include a first chip conductive pad 50c. The second semiconductor die CH2 may include a second chip conductive pad 50f. The first and second semiconductor dies CH1 and CH2 may be bonded to the interposer substrate IPS through the internal connection terminals IB. A second underfill layer UF2 may be interposed between the first semiconductor die CH1 and the interposer substrate IPS. A second dummy structure DST2 and a second signal connection structure RST2 may be disposed between the interposer substrate IPS and the first semiconductor die CH1. The second dummy structure DST2 and the second signal connection structure RST2 may be the same/similar to those described with reference to FIGS. 1 to 11C.

A third underfill layer UF3 may be interposed between the second semiconductor die CH2 and the interposer substrate IPS. A third dummy structure DST3 and a third signal connection structure RST3 may be disposed between the interposer substrate IPS and the second semiconductor die CH2. The third dummy structure DST3 and the third signal connection structure RST3 may be the same/similar to those described with reference to FIGS. 1 to 11C.

A thermal interface material layer TIM may be interposed between the heat dissipation member HS and the first and second semiconductor dies CH1 and CH2. Other structures may be the same/similar to those described above.

In the semiconductor package according to the present disclosure, the dummy structure may be disposed on the corner regions of the first semiconductor die, and the distance between the first semiconductor die and the second semiconductor die on the corner regions may be narrowed to solve the unfill problem of the underfill layer, and the underfill layer may not be exposed to the side of the mold layer to prevent/inhibit the non-wet defects in the solder layer. Accordingly, the reliability of the semiconductor package may be improved.

While embodiments are described above, a person skilled in the art may understand that many modifications and variations are made without departing from the spirit and scope of the present disclosure defined in the following claims. Accordingly, the example embodiments of the present disclosure should be considered in all respects as illustrative and not restrictive, with the spirit and scope of the present disclosure being indicated by the appended claims. The embodiments of FIGS. 1 through 15 can be combined with each other.

What is claimed is:

1. A semiconductor package comprising:
a first semiconductor die;
a second semiconductor die on the first semiconductor die; and
an underfill layer between the first semiconductor die and the second semiconductor die,
wherein the first semiconductor die comprises:
a first substrate comprising a main region and first corner regions, wherein the first corner regions overlap the second semiconductor die, wherein the first corner regions are adjacent to respective corners of the second semiconductor die, and wherein the main region overlaps a center of the second semiconductor die in a first direction;
redistribution patterns that are on the first substrate and comprise dummy wirings and signal wirings;
a redistribution insulating layer on the redistribution patterns; and
conductive pads that are on the redistribution insulating layer and comprise dummy pads and signal pads,
wherein a pattern density of a first set of the conductive pads on the first corner regions is greater than a pattern density of a second set of the conductive pads on the main region.

2. The semiconductor package of claim 1, wherein a distance between a first one of the first corner regions and a respective one of the dummy pads is less than a distance between the first one of the first corner regions and a respective one of the signal pads.

3. The semiconductor package of claim 1, wherein some of the dummy pads are between ones of the signal pads.

4. The semiconductor package of claim 1, wherein the dummy pads are not on the main region.

5. The semiconductor package of claim 1, wherein a first dummy wiring of the dummy wirings electrically connects a first dummy pad from among the dummy pads and a first signal pad from among the signal pads, and wherein the first signal pad is adjacent to the first dummy pad.

6. The semiconductor package of claim 1, wherein a width of each of the dummy pads is greater than a width of each of the signal pads.

7. The semiconductor package of claim 1, wherein the second semiconductor die further comprises:
conductive bumps; and
a second substrate on the conductive bumps,
wherein the conductive bumps are electrically connected to respective ones of the signal pads and respective ones of the dummy pads.

8. The semiconductor package of claim 1, wherein a first end of a first one of the dummy wirings is respectively connected to one of the dummy pads, and wherein a second end of the first one of the dummy wirings extends toward one of the first corner regions.

9. The semiconductor package of claim 1, wherein:
the first substrate further comprises second corner regions that overlap the second semiconductor die and are respectively between ones of the first corner regions and the main region,
a third set of the conductive pads are on the second corner regions, and
a pattern density of the third set of the conductive pads is less than the pattern density of the first set of the conductive pads and is greater than the pattern density of the second set of the conductive pads.

10. The semiconductor package of claim 9, wherein a distance between a first one of the first corner regions of the first semiconductor die and a respective corner of the second semiconductor die is less than a distance between the first one of the first corner regions of the first semiconductor die and a first one of the second corner regions of the first semiconductor die.

11. The semiconductor package of claim 1, wherein each of the first corner regions comprises a triangular shape, a square shape, a diamond shape, or a polygonal shape.

12. The semiconductor package of claim 1, wherein a first one of the conductive pads on the first corner regions comprises a first width, and wherein a first one of the conductive pads on the main region comprises a second width that is less than the first width.

13. The semiconductor package of claim 1, wherein the conductive pads on the first corner regions comprise a polygonal shape, and the conductive pads on the main region comprise a circular shape.

14. The semiconductor package of claim 1, wherein the dummy wirings comprise at least one of a line shape, an “L” shape, and a ring shape.

15. A semiconductor package comprising:
a first semiconductor die;
a second semiconductor die on the first semiconductor die;
a mold layer that overlaps the second semiconductor die and the first semiconductor die;
external connection terminals on the first semiconductor die;
internal connection members between the first semiconductor die and the second semiconductor die; and
an underfill layer in a space between the first semiconductor die and the second semiconductor die,
wherein the first semiconductor die comprises:
a first substrate comprising a main region and first corner regions, wherein the first corner regions overlap the second semiconductor die, wherein the first corner regions are adjacent to respective corners of the second semiconductor die, and wherein the main region overlaps a center of the second semiconductor die in a first direction;
through vias that extend into the main region of the first substrate;
redistribution patterns that are on the first substrate and comprise dummy wirings and signal wirings;
a redistribution insulating layer on the redistribution patterns; and
conductive pads that are on the redistribution insulating layer and comprise dummy pads and signal pads,
wherein a distance between a first set of the conductive pads on the first corner regions is less than a distance between a second set of the conductive pads on the main region,
wherein the second semiconductor die comprises:
a second substrate;
an interlayer insulating layer on a lower surface of the second substrate;
internal wirings in the interlayer insulating layer; and
conductive bumps on the interlayer insulating layer, and
wherein the internal connection members electrically connect at least some of the conductive bumps to ones of the signal pads.

16. The semiconductor package of claim 15, wherein at least some of the dummy pads are between ones of the signal pads.

17. The semiconductor package of claim 15, wherein a first one of the dummy pads comprises a first width, and wherein a first one of the signal pads comprises a second width that is less than the first width.

18. The semiconductor package of claim 15, wherein:
the first substrate further comprises second corner regions that overlap the second semiconductor die in the first direction and are respectively between the first corner regions and the main region,
wherein the conductive pads are on the second corner regions, and
wherein a pattern density of a third set of the conductive pads on the second corner regions is less than a pattern density of the first set of the conductive pads on the first corner regions and is greater than a pattern density of the second set of the conductive pads on the main region.

19. A semiconductor package comprising:
a first semiconductor die;
a second semiconductor die on the first semiconductor die; and
an underfill layer between the first semiconductor die and the second semiconductor die,
wherein the first semiconductor die comprises:
a substrate comprising a main region and first corner regions, wherein the first corner regions overlap the second semiconductor die, wherein the first corner regions are adjacent to respective corners of the second semiconductor die, and wherein the main region overlaps a center of the second semiconductor die in a first direction;
signal wirings and dummy wirings on the substrate;
a redistribution insulating layer that is on the signal wirings and the dummy wirings; and
conductive pads on the redistribution insulating layer,
wherein the conductive pads comprise signal pads and dummy pads, and
wherein a first one of the dummy wirings electrically connects a first one of the dummy pads and a first one of the signal pads.

20. The semiconductor package of claim 19, wherein a distance between a first set of the conductive pads on the first corner regions is less than a distance between a second set of the conductive pads on the main region.
